(19) United States
(12) Patent Application Publication
(10) Pub. No.: US 2025/0333355 A1
(43) Pub. Date: Oct. 30, 2025

(54) LASER-BONDED ASSEMBLIES COMPRISING HEREMETICALLY-SEALED GLASS STRUCTURES AND COVER GLASS

(71) Applicant: CORNING INCORPORATED, CORNING, NY (US)

(72) Inventors: Jason Roy Grenier, Horseheads, NY (US); Farrokh Sheibani, Chestnut Hill, MA (US); Kristopher Allen Wieland, Painted Post, NY (US)

(21) Appl. No.: 19/089,803

(22) Filed: Mar. 25, 2025

Related U.S. Application Data
(60) Provisional application No. 63/639,819, filed on Apr. 29, 2024.

(51) Int. Cl. C03C 27/02; B32B 7/12; B32B 17/06

(52) U.S. Cl. CPC C03C 27/02; B32B 7/12; B32B 17/061

(57) ABSTRACT

A laser-bonded assembly, in embodiments, comprises a glass structure, a metal foil, and a first cover glass. The glass structure includes a first glass substrate that defines a first major surface and a second glass substrate that defines a second major surface that faces opposite the first major surface. The glass structure further includes a peripheral edge that extends between the first and second major surfaces about a periphery thereof. The laser-bonded assembly further comprises a metal foil configured to encircle the peripheral edge. The metal foil is connected to the glass structure via foil-glass laser bonds. The laser-bonded assembly further comprises a first cover glass that is connected to the glass structure and/or the metal foil. The laser-bonded assembly further comprises a frame disposed adjacent the first cover glass. The glass structure and the metal foil are at least partially surrounded by the frame and the first cover glass.

### CROSS REFERENCE TO RELATED APPLICATION

This application claims the benefit of priority under 35 U.S.C. § 119 of U.S. Provisional Application Ser. No. 63/639,819 filed on Apr. 29, 2024, of which is incorporated herein by reference in its entirety.

### FIELD

The present disclosure relates to sealed glass assemblies. In particular, the present disclosure relates to laser-bonded assemblies comprising hermetically-sealed glass structures and cover glass.

### BACKGROUND

Glass structures can be laser bonded to metal foils to form hermetically-sealed glass structure. Such hermetically-sealed glass structures are increasingly employed in consumer electronic devices and other devices that may benefit from a hermetic environment. Consumer electronic devices are often subject to increasing durability requirements (e.g., scratch resistance, drop survivability, etc.) while also meeting hermeticity requirements. However, some existing hermetically-sealed glass structures may not be sufficiently robust to meet both of these requirements.

Consequently, it would be advantageous to provide hermetically-sealed glass structures with various arrangements of cover glass to form laser-bonded assemblies that overcome the issues of existing hermetically sealed glass structures.

### SUMMARY

A first aspect of the present disclosure includes a laser-bonded assembly, comprising: a glass structure that includes (i) a first glass substrate defining a first major surface, (ii) a second glass substrate disposed adjacent the first glass substrate and defining a second major surface that faces opposite the first major surface, and (iii) a peripheral edge extending between the first and second major surfaces about a periphery of the glass structure; a metal foil encircling the peripheral edge about the periphery of the glass structure, the metal foil connected to the glass structure via one or more foil-glass laser bonds; a first cover glass connected to one or more of the glass structure and the metal foil; and a frame disposed adjacent the first cover glass, the glass structure and the metal foil at least partially surrounded by the frame and the first cover glass.

A second aspect of the present disclosure includes a laser-bonded assembly, comprising: a glass structure that includes (i) a first glass substrate defining a first major surface, (ii) a second glass substrate disposed adjacent the first glass substrate and defining a second major surface that faces opposite the first major surface, and (iii) a peripheral edge extending between the first and second major surfaces about a periphery of the glass structure; a polymer seal encircling the peripheral edge about the periphery of the glass structure; a first cover glass disposed adjacent the polymer seal and the glass structure; and a second cover glass disposed adjacent the polymer seal and the glass structure and opposite the first cover glass, the glass structure and the polymer seal disposed in a cavity between the first and second cover glasses, wherein the second cover glass is connected to one or more of the glass structure and the first cover glass via one or more glass-glass laser bonds.

### BRIEF DESCRIPTION OF THE DRAWINGS

FIG. 1 is a schematic cross-sectional view of a laser-bonded assembly that comprises a hermetically-sealed glass structure, a metal foil, a frame, and at least one cover glass according to embodiments;

FIG. 2 is a schematic cross-sectional view of a laser-bonded assembly that includes a hermetically-sealed glass structure, a metal foil, a frame, and at least two cover glasses according to embodiments;

FIG. 3 is a schematic cross-sectional view of a laser-bonded assembly that includes a hermetically-sealed glass structure, a metal foil configured differently than the metal foil of FIG. 1 or FIG. 2, a frame, and at least two cover glasses according to embodiments;

FIG. 4 is a schematic cross-sectional view of a laser-bonded assembly that includes a hermetically-sealed glass structure, a polymer seal, and at least two cover glasses according to embodiments;

FIG. 5 is a schematic cross-sectional view of a laser-bonded assembly that includes a hermetically-sealed glass structure, a polymer seal configured differently than the polymer seal of FIG. 4, and at least two cover glasses according to embodiments;

FIG. 6 is a schematic cross-sectional view of a laser-bonded assembly that is similar to the laser-bonded assembly of FIG. 5 except that at least one laser bond is omitted between the glass structure and the cover glass;

FIG. 7 is a schematic cross-sectional view depicts an embodiment of the glass structure and metal foil(s) used with the laser-bonded assemblies of FIG. 1 and FIG. 2;

FIG. 8 is a schematic cross-sectional view depicts an embodiment of the glass structure and metal foil used with the laser-bonded assembly of FIG. 3;

FIG. 9 is a simplified schematic top view of the laser-bonded assembly of FIG. 1 to illustrate aspects of one or more foil-glass laser bonds;

FIG. 10 is a simplified schematic top view of the laser-bonded assembly of FIG. 2 to illustrate aspects of one or more foil-glass laser bonds;

FIG. 11 is a simplified schematic top view of the laser-bonded assembly of FIG. 3 to illustrate aspects of one or more foil-glass laser bonds and one or more glass-glass laser bonds thereof; and

FIG. 12 is a simplified schematic top view of the laser-bonded assembly of FIG. 4 to illustrate aspects of one or more glass-glass laser bonds thereof.

### DETAILED DESCRIPTION

For the purposes of promoting an understanding of the principles of the disclosure, reference will now be made to the embodiments illustrated in the drawings and described in the following written specification. It is understood that no limitation to the scope of the disclosure is thereby intended. It is further understood that the present disclosure includes any alterations and modifications to the illustrated embodiments and includes further applications of the principles disclosed herein as would normally occur to one skilled in the art to which this disclosure pertains.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point, and independently of the other end-point.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range was explicitly recited. As an illustration, a numerical range of “about 1 to about 5” should be interpreted to include not only the explicitly recited values of about 1 to about 5, but also to include individual values and sub-ranges within the indicated range. Thus, included in this numerical range are individual values such as 2, 3, and 4, the sub ranges such as from 1-3, from 2-4, from 3-5, etc., as well as 1, 2, 3, 4, and 5 individually. The same principle applies to ranges reciting only one numerical value as a minimum or maximum. Furthermore, such an interpretation should apply regardless of the breadth of the range or the characteristics being described by the range.

The terms “substantial,” “substantially,” and variations thereof as used herein, unless defined elsewhere in association with specific terms or phrases, are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

Directional terms as used herein—for example up, down, right, left, front, back, top, bottom, above, below, and the like—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

“Hermetically bonded,” “hermetically sealed,” or the like, as described herein, refers to an assembly that includes a hermetic seal in accordance with MIL-STD-750E, Test Method 1071.9.

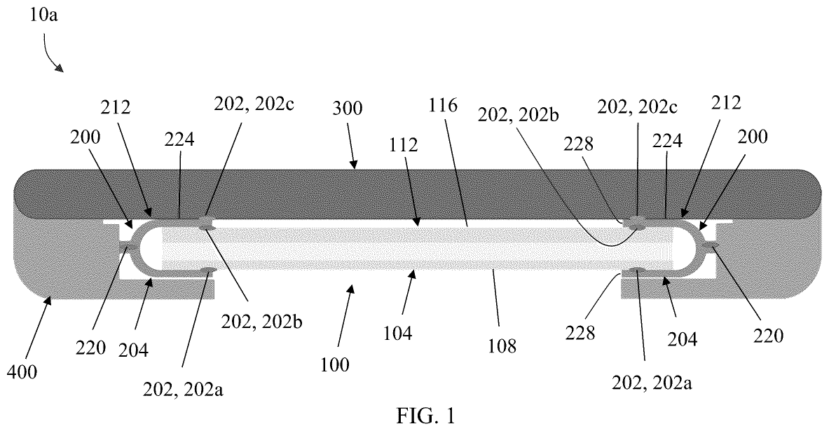

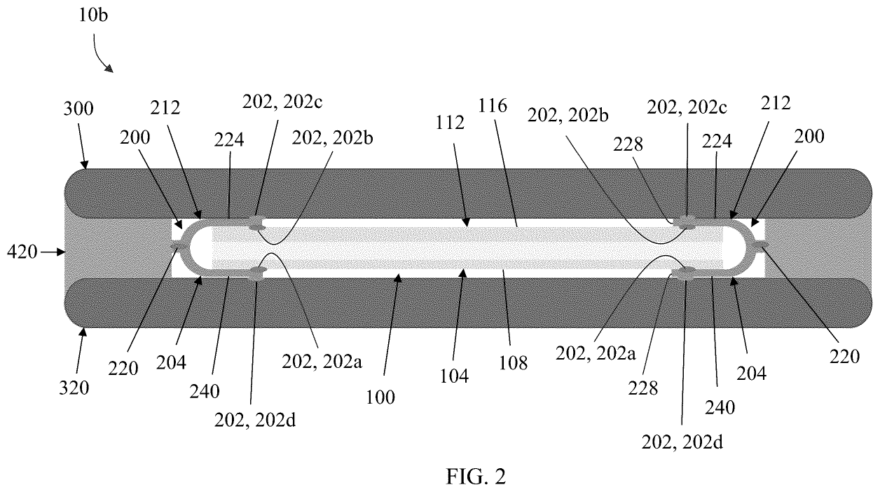

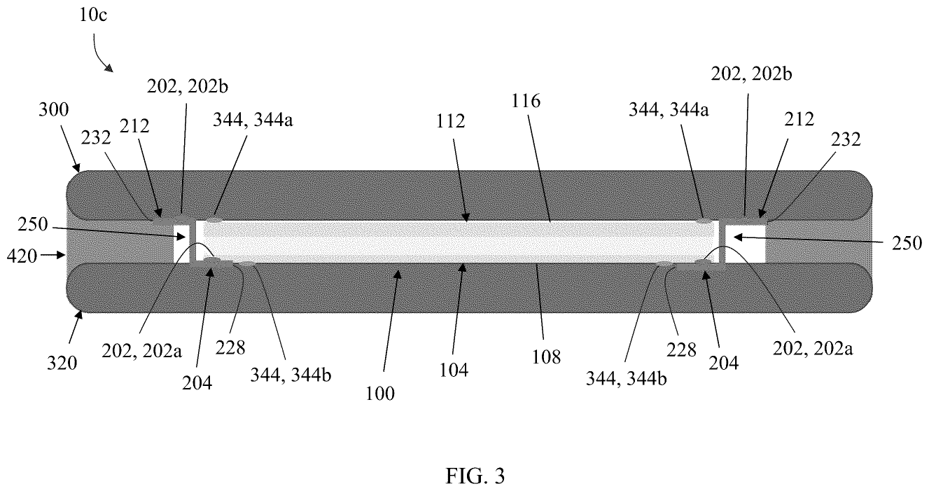

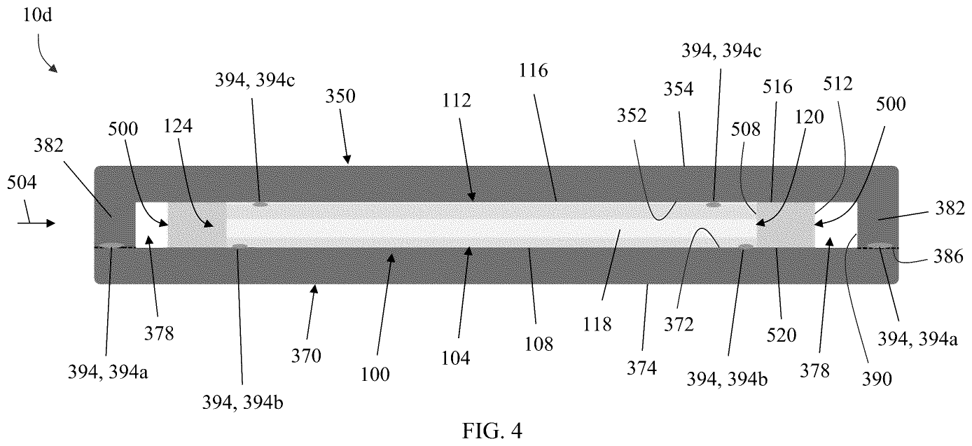

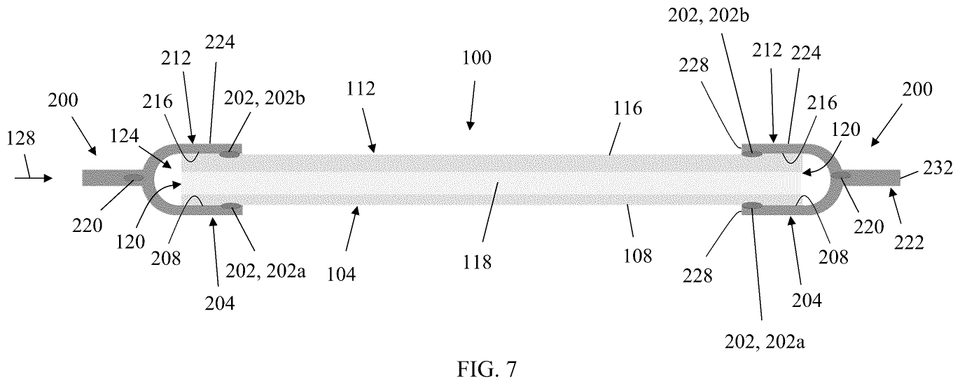

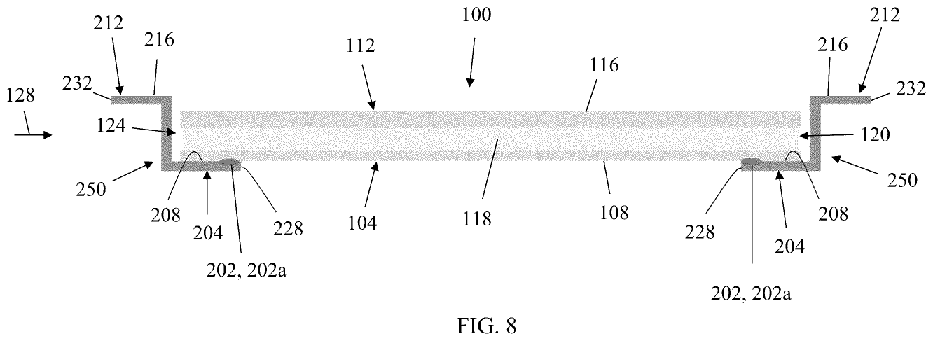

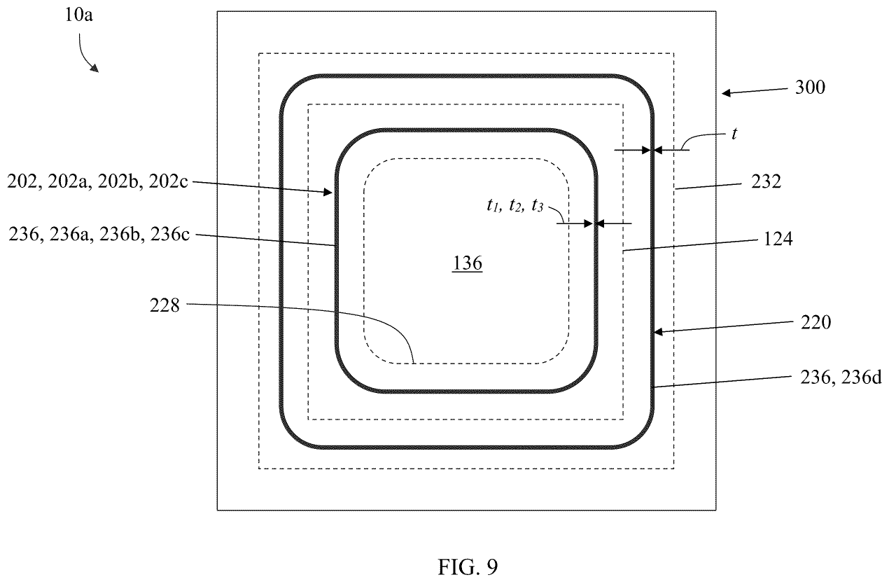

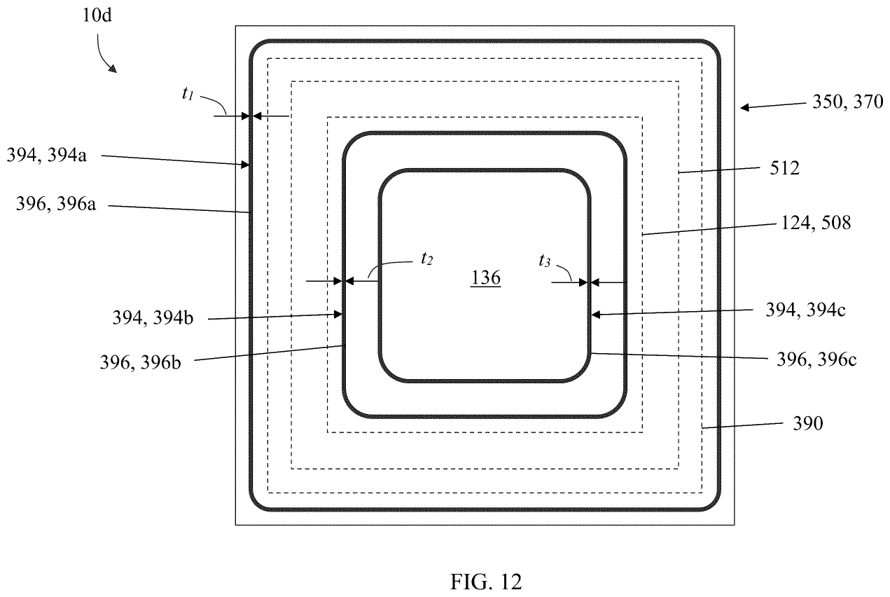

Disclosed herein are embodiments of laser-bonded assemblies that are configured to address one or more of the edge strength and fixturing issues described hereinabove. FIGS. 1-3 illustrate laser-bonded assemblies that utilize one or more metal foils in connection with other structures to form hermetically sealed packages. FIGS. 4-6 illustrate-laser-bonded assemblies that utilize a polymer seal instead of the one or more metal foils to form hermetically sealed packages. In the various embodiments, the laser-bonded assemblies each include a glass structure that comprises at least two glass substrates disposed adjacent to one another. FIG. 7 depicts an embodiment of the glass structure and metal foil(s) used with the laser-bonded assemblies of FIGS. 1 and 2. FIG. 8 depicts an embodiment of the glass structure and metal foil used with the laser-bonded assembly of FIG. 3. FIGS. 9-11 are simplified schematic top view of the laser-bonded assemblies of FIGS. 1-3, respectively, that illustrate the relative positions of the laser bonds used to connect and/or seal the various elements of the laser-bonded assemblies. FIG. 12 is a simplified schematic top view of the laser-bonded assembly of FIG. 4 that illustrates the relative positions of the laser bonds used to connect and/or seal the various elements of the laser-bonded assemblies.

Referring now to FIGS. 1 and 7, a laser-bonded assembly 10a is shown in a first configuration. The laser-bonded assembly 10a in the first configuration can be interchangeably referred to as the first laser-bonded assembly 10a for case of description though such reference should not be considered to limit the scope of the disclosure. The first laser-bonded assembly 10a comprises a glass structure 100 that is configured to be hermetically sealed. As best shown in FIG. 7, the glass structure 100 includes a first glass substrate 104 that defines a first major surface 108 of the glass structure 100 and a second glass substrate 112 that is disposed adjacent the first glass substrate 104 and defines a second major surface 116 of the glass structure 100. The second major surface 116 faces opposite the first major surface 108, as shown in FIGS. 1 and 7.

In embodiments, the first glass substrate 104 and the second glass substrate 112 are not in direct contact with each other such that one or more other glass substrates, a polymer layer, or (electronic) components (e.g., interchangeably referred to as “fill” or “fill layer(s)”) can be placed therebetween. For example, the glass structure 100 shown in FIGS. 1 and 7 includes a fill layer 118 disposed between the first glass substrate 104 and the second glass substrate 112. Positioning the other glass substrates, polymer layer, or (electronic) components between the first glass substrate 104 and the second glass substrate 112 protects the other glass substrate(s), polymer layer, or (electronic) components from environmental conditions, such as pressure changes, moisture, bodily fluids, or the like. In embodiments, the first glass substrate 104 and the second glass substrate 112 can be in direct contact (not shown) with no fill layers(s) disposed therebetween.

The glass structure 100 further includes a peripheral edge or side 120 that extends between the first major surface 108 and the second major surface 116 about a periphery 124 (e.g., outermost portion or perimeter) of the glass structure 100. When viewed in a direction perpendicular to the first major surface 108 and the second major surface 112 (e.g., interchangeably referred to as a thickness direction), the periphery 124 of the glass structure 100 can have any shape, such as a shape that includes linear portion(s), curved portion(s), or both. In embodiments, the periphery 124 of the glass structure 100 can have a free-form shape (e.g., no straight lines). In embodiments, the peripheral edge 120 comprises surfaces of one or more of the first glass substrate 104, the second glass substrate 112, and the fill layer(s) that abut and/or define the periphery 124 of the glass structure 100.

The peripheral edge 124 can comprise a continuous surface that includes portions of the surfaces of the first glass substrate 104, the second glass substrate 112, and the fill layer(s), such as shown in FIGS. 1 and 7. The peripheral edge 124 can comprise a continuous surface that includes portions of the surfaces of the first glass substrate 104 and the second glass substrate 112 when the first glass substrate 104 and the second glass substrate 112 are in direct contact (e.g., the glass structure does not include fill layers(s)). The peripheral edge 124 can comprise a discontinuous surface that extends between the first major surface 108 and the second major surface 116 such as when the first glass substrate 104 and the second glass substrate 112 are adjacent but not in direct contact with one another and no fill layer(s) is/are disposed therebetween.

In embodiments, the first glass substrate 104 and the second glass substrate 112 can comprise a refractive index greater than or equal to 1.4 and less than or equal to 2.4. In embodiments, the first glass substrate 104 and the second glass substrate 112 can comprise a refractive index greater than or equal to 1.4, greater than or equal to 1.5, or even greater than or equal to 1.6. In embodiments, the first glass substrate 104 and the second glass substrate 112 can comprise a refractive index less than or equal to 2.4, less than or equal to 2.3, or even less than or equal to 2.2. In embodiments, the first glass substrate 104 and the second glass substrate 112 can comprise a refractive index greater than or equal to 1.4 and less than or equal to 2.4, greater than or equal to 1.4 and less than or equal to 2.3, greater than or equal to 1.4 and less than or equal to 2.2, greater than or equal to 1.5 and less than or equal to 2.4, greater than or equal to 1.5 and less than or equal to 2.3, greater than or equal to 1.5 and less than or equal to 2.2, greater than or equal to 1.6 and less than or equal to 2.4, greater than or equal to 1.6 and less than or equal to 2.3, or even greater than or equal to 1.6 and less than or equal to 2.2, or any and all sub-ranges formed from any of these endpoints. It should be understood that, in some embodiments, the first glass substrate 104 and the second glass substrate 112 can have refractive index values which are different from one another.

In embodiments, the first glass substrate 104 and the second glass substrate 112 can comprise a glass or a glass-ceramic. By way of non-limiting examples, the first glass substrate 104 and the second glass substrate 112 can comprise borate glass, silicoborate glass, phosphate-based glass, silicon carbide glass, soda-lime silicate glass, aluminosilicate glass, alkali-aluminosilicate glass, borosilicate glass, alkali-borosilicate glass, aluminoborosilicate glass, alkali-alumino-borosilicate glass, or alkali-aluminosilicate glass. In embodiments in which a relatively high refractive index glass (e.g., refractive index greater than or equal to 1.4 and less than or equal to 2.4) is desired, the first glass substrate 104 and the second glass substrate 112 can comprise borate glass, or silicoborate glass. In embodiments, the first glass substrate 104 and the second glass substrate 112 can be chemically strengthened, chemically tempered, and/or thermally tempered. Non-limiting examples of suitable commercially available glass substrates include EAGLE XG®, Lotus™, Willow®, and Gorilla® glasses from Corning Incorporated, including chemically strengthened, chemically tempered, and/or thermally tempered versions thereof. In embodiments, glasses and glass-ceramics that have been chemically strengthened by ion exchange can be suitable as substrates. In other embodiments, the first glass substrate 104 and/or the second glass substrate 112 can be a strengthened glass-to-glass laminate.

In embodiments, the first glass substrate 104 and the second glass substrate 112 can comprise a coating thereon (not shown). In embodiments, the coating can comprise a similar refractive index as the first glass substrate 104 and the second glass substrate 112. In embodiments, the coating can comprise a polymer coating, an antireflection (AR) coating, an oliphobic coating, an anti-glare coating, or a scratch resistant coating.

Referring still to FIGS. 1 and 7, the first laser-bonded assembly 10a further comprises a metal foil 200 that is configured to encircle the peripheral edge 120 about the periphery 124 of the glass structure 100. As used herein, the terms “encircle,” “encircles,” “encircling”, or the like mean that the metal foil 200 is shaped and/or positioned to encompass, surround, and/or cover an entirety of the peripheral edge 120 (e.g., the surfaces that form or define the peripheral edge) when viewed in a direction parallel to the first major surface 108 and the second major surface 116 from a position laterally outside or external the glass structure 100 and the metal foil 200, such as illustrated by the arrow 128 in FIG. 7.

The metal foil 200 is connected to the glass structure 100 via one or more foil-glass laser bonds 202. As used herein, a “foil-glass laser bond” refers to a mechanical connection that is made (directly) between the metal foil 200 and a glass material (e.g., glass or glass ceramic) of another component or part of the laser-bonded assembly and that is formed via a laser beam directed proximate a contact location between the metal foil 200 and the glass material. Aspects of fixtures and processes that can be used to form the one or more foil-glass laser bonds 202 are described later in this disclosure.

In embodiments, the first glass substrate 108 and the second glass substrate 112 can be formed from a material that is substantially transparent to a selected wavelength of the laser beam used to connect the metal foil to the glass. The term “substantially transparent” means that the selected wavelength of the laser beam transmits through the material without being substantially absorbed or scattered. For example, in embodiments, a material that is substantially transparent to a selected wavelength of the laser beam can be a material that exhibits a transmittance greater or equal to 90% at the selected wavelength. In embodiments, the first glass substrate 108 and the second glass substrate 112 can optionally be substantially transparent to a wavelength of light greater than or equal to 300 nm and less than or equal to 1100 nm or even greater than or equal to 330 nm and less than or equal to 750 nm.

In embodiments, the first glass substrate 108 and the second glass substrate 112 can be subjected to surface preparation prior to connecting the first glass substrate 108 and the second glass substrate 112 to the metal foil 200. For example, in embodiments, the first glass substrate 108 and the second glass substrate 112 can be polished until the surfaces thereof exhibit comparatively lower surface roughness values, which can enhance bonding to the metal foil 200. In embodiments, the first major surface 108 of the first glass substrate 104 and/or the second major surface 116 of the second glass substrate 112 can be polished until the first major surface 108 and/or the second major surface 116 exhibit an average surface roughness (Ra) less than or equal to 1 μm, less than or equal to 0.5 μm, or even less than or equal to 0.25 μm.

The smooth surface can allow the first glass substrate 108 and the second glass substrate 112 to be placed in close contact with the metal foil 200 (e.g., within a few μm of one another). In addition, the first glass substrate 108 and the second glass substrate 112 can be cleaned with water and/or solvents to remove any debris present on the surface and/or to remove any material (oil, grease, etc.). Removal of any debris can allow the first glass substrate 108 and the second glass substrate 112 to be placed in close contact with the metal foil 200 to better facilitate laser bonding of the metal foil 200 to the glass structure 100.

As best shown in FIG. 7, the metal foil 200 comprises a first foil portion 204 that extends towards the glass structure 100 and connects to the first major surface 108 at a first contact location. In embodiments, the first foil portion 204 comprises a first foil surface 208 that is connected to the first major surface 108 at the first contact location via a first foil-glass laser bond 202a of the one or more foil-glass laser bonds 202. The metal foil 200 further comprises a second foil portion 212 that extends towards the glass structure 100 and connects to the second major surface 116 at a second contact location. In embodiments, the second foil portion 212 comprises a second foil surface 216 that is connected to the second major surface 116 at the second contact location via a second foil-glass laser bond 202b of the one or more foil-glass laser bonds 202.

In embodiments, the metal foil 200 can be a monolithic body such that the first foil portion 204 and the second foil portion 212 are integral features of the monolithic body and no further bonding (e.g., laser bonding or otherwise) is needed to hermetically seal the glass structure 100 after the first foil portion 204 and the second foil portion 212 are connected to the glass structure 100 via the first foil-glass laser bond 202a and the second foil-glass laser bond 202b, respectively. In embodiments, the first foil portion 204 and the second foil portion 212 can be separate, distinct bodies that are joined together via a foil-foil laser bond 220 to hermetically seal the glass structure 100 after the first foil portion 204 and the second foil portion 212 are connected to the glass structure 100 via the first foil-glass laser bond 202a and the second foil-glass laser bond 202b, respectively. As used herein, a “foil-foil laser bond” refers to a mechanical connection that is made (directly) between the different portions of the metal foil 200 (e.g., the first foil portion 204 and the second foil portion 212) and that is formed via a laser beam directed proximate a contact location between the different portions of the metal foil 200. In embodiments, the metal foil 200 comprises a third foil portion 222 that extends away from the glass structure 100, the first foil portion 204, and the second foil portion 212. In embodiments, the foil-foil laser bond 220 is disposed along the third foil portion 222. Aspects of fixtures and processes that can be used to form the foil-foil laser bond 220 are described later in this disclosure.

In embodiments, the metal foil 200 comprises an inner periphery 228 (e.g., innermost perimeter) and an outer periphery 232 (e.g., outermost perimeter). The glass structure 100 comprises a central region 136 (FIG. 9) through which one or more of the first glass substrate 104, the second glass substrate 112, and the (optional) fill layer 118 can interact (e.g., directly and/or indirectly) with the external environment surrounding the first laser-bonded assembly 10a. In embodiments, the inner periphery 228 of the metal foil 200 encircles at least a portion of the central region 136 of the glass structure 100 so as to expose (e.g., not cover) the central region 136. In embodiments, a distal end of the first foil portion 204 of the metal foil 200 defines the inner periphery 228 on a first side (e.g., a bottom side) of the first laser-bonded assembly 10a. In embodiments, a distal end of the second foil portion 212 defines the inner periphery 228 on a second side (e.g., a top side) of the first laser-bonded assembly 10a. In embodiments, a distal end of the third foil portion 222 defines the outer periphery 232.

In embodiments, the first foil portion 204 and the second foil portion 212 of the metal foil 200 can be connected to the first glass substrate 200 and second glass substrate 202, respectively, such that the inner periphery 228 on the first side (e.g., the bottom side) of the first laser-bonded assembly 10a at least partially overlaps with the inner periphery 228 on the second side (e.g., the top side) of the first laser-bonded assembly 10a, thereby exposing the first glass substrate 104 and the second glass substrate 112 through the inner periphery 228 on the first side and the inner periphery 228 on the second side and providing a window through the glass structure 100. In embodiments, such as illustrated in FIGS. 1, 7, and 9, the inner periphery 228 on the first side is aligned with the inner periphery 228 on the second side, such that the inner periphery 228 on the first side and the inner periphery 228 on the second side completely overlap.

In embodiments, the first foil portion 204 can have a thickness less than or equal to 50 μm. In embodiments, the first foil portion 204 can have a thickness greater than or equal to 3 μm and less than or equal to 50 μm. In embodiments, the first foil portion 204 can have a thickness greater than or equal to 5 μm, greater than or equal to 10 μm, or even greater than or equal to 20 μm. In embodiments, the first foil portion 204 can have a thickness less than or equal to 50 μm, less than or equal to 40 μm, or even less than or equal to 30 μm. In embodiments, the first foil portion 204 can have a thickness greater than or equal to 3 μm and less than or equal to 50 μm, greater than or equal to 5 μm and less than or equal to 40 μm, greater than or equal to 5 μm and less than or equal to 30 μm, greater than or equal to 10 μm and less than or equal to 50 μm, greater than or equal to 10 μm and less than or equal to 40 μm, greater than or equal to 10 μm and less than or equal to 30 μm, greater than or equal to 20 μm and less than or equal to 50 μm, greater than or equal to 20 μm and less than or equal to 40 μm, or even greater than or equal to 20 μm and less than or equal to 30 μm, or any and all sub-ranges formed from any of these endpoints.

In embodiments, the first foil portion 204 can comprise aluminum, aluminum alloys, stainless steel, nickel, nickel alloys, silver, silver alloys, titanium, titanium alloys, tungsten, tungsten alloys, gold, gold alloys, copper, copper alloys, bronze, iron, or a combination thereof. In embodiments, the first foil portion 204 can comprise a metal in combination with another non-metal material.

In embodiments, the first foil portion 204 can be formed from a material that has a melting point that allows for successful bonding to the glass substrate. In embodiments, the first foil portion 204 can comprise a melting point less than or equal to 1800° C., less than or equal to 1700° C., or even less than or equal to 1600° C.

In embodiments, the first foil portion 204 can be formed from a material that is substantially opaque to a selected wavelength of a laser beam. The term “substantially opaque” means that the selected wavelength of the laser beam is substantially absorbed when the laser beam contacts the material rather than transmitted through the material. For example, in embodiments, a material that is substantially opaque to the selected wavelength of the laser beam can be a material that exhibits an absorbance greater than or equal to 35% at the wavelength.

In embodiments, the first foil portion 204 can have the same or a similar average surface roughness (Ra) as the first glass substrate 104 to similarly allow the first glass substrate 104 to be placed in close contact with the first foil portion 204. In embodiments, the second foil portion 212 can have substantially similar or the same properties as the first foil portion 204 as described hereinabove.

Referring still to FIGS. 1 and 7, the first laser-bonded assembly 10a further comprises a first cover glass 300 that is connected to one or more of the glass structure 100 and the metal foil 200. As best shown in FIG. 1, the second foil portion 212 of the metal foil 200 is configured to connect to the first cover glass 300 at a third contact location. In embodiments, the second foil portion 212 comprises a third foil surface 224 that is connected to the first cover glass 300 at the third contact location via a third foil-glass laser bond 202c of the one or more foil-glass laser bonds 202. In embodiments, the third foil surface 224 of the second foil portion 212 is additionally or alternatively connected to the first cover glass 300 at the third contact location via optically clear adhesive (OCA).

In embodiments, the first cover glass 300 can have a refractive index that is the same as or similar to the refractive index of one or both of the first glass substrate 104 and the second glass substrate 112. In embodiments, the first cover glass 300 can have a refractive index that is different than the refractive index of one or both of the first glass substrate 104 and the second glass substrate 112. In embodiments, the first cover glass 300 can comprise a glass or a glass ceramic that is the same as or similar to the glass or the glass ceramic of one or both of the first glass substrate 104 and the second glass substrate 112. In embodiments, the first cover glass 300 can comprise a glass or a glass ceramic that is different than the glass or the glass ceramic of one or both of the first glass substrate 104 and the second glass substrate 112.

In embodiments, the first cover glass 300 can be chemically strengthened, chemically tempered, and/or thermally tempered. Non-limiting examples of suitable commercially available glass material for the first cover glass 300 include EAGLE XG®, Lotus™, Willow®, and Gorilla® glasses from Corning Incorporated, including chemically strengthened, chemically tempered, and/or thermally tempered versions thereof. In embodiments, glasses and glass ceramics that have been chemically strengthened by ion exchange can be suitable as the first cover glass 300. In embodiments, the first cover glass 300 can be a strengthened glass-to-glass laminate. In an exemplary embodiment, the first cover glass 300 is cut to size, edge-finished, and chemically strengthened via ion-exchanged such that the surfaces and edges thereof are substantially strengthened, especially compared to cover glass that is not edge-finished and not chemically strengthened (e.g., via ion exchange).

In embodiments in which the refractive index of the first cover glass 300 is different than the refractive index of one or both of the first glass substrate 104 and the second glass substrate 112 of the glass structure 100, an index-matching material can be incorporated at the interface(s) therebetween. In such embodiments, the index-matching material can remove the interface(s) and the resulting problems from interface(s). In embodiments, the index-matching material can be a liquid. In embodiments, the index-matching material can be compliant such that the index-matching material does not transfer stresses from the first cover glass to the glass structure. In embodiment, the first cover glass 300 can be formed from a glass that is compatible with chemical strengthening and has the same refractive index as the glass structure such that an optically clear adhesive can be used therebetween.

Referring still to FIGS. 1 and 7, the first laser-bonded assembly 10a further comprises a frame 400 that is disposed adjacent the first cover glass 300. As best shown in FIG. 1, the glass structure 100 and the metal foil 200 are at least partially surrounded by the frame 400 and the first cover glass 300. The frame 400 is preferably formed from metal, but the frame 400 can be formed from other materials, such as plastic, reinforced plastic (e.g., carbon-fiber filled, glass-filled, etc.), or similarly rigid and impact-resistant materials that can support the first cover glass 300 when connected to the frame 400. In embodiments, the first cover glass 300 is mechanically attached to the frame 400. The first cover glass 300 can be mechanically attached to the frame 400 in a manner similar to how the cover glass is connected to the metal frames of cellular phones. Such a mechanical attachment can handle the stresses and impacts on the first cover glass 300. In embodiments, the first cover glass 300 is connected to the glass structure 100 and/or the metal foil 200 (e.g., forming a sub-assembly comprising the glass structure 100, the metal foil 200, and the first cover glass 300) before the first cover glass 300 is mechanically attached to the frame 400.

Referring now to FIG. 9, a simplified schematic top view of the first laser-bonded assembly 10a of FIG. 1 is shown to illustrate aspects of the one or more foil-glass laser bonds 202 and the (optional) foil-foil laser bond 220. The view of FIG. 9 is simplified in that most features of the first laser-bonded assembly 10a are shown fully transparent and the frame 400 is not shown. The periphery 124 of the glass structure 100, the inner periphery 228 of the metal foil 200, and the outer periphery 232 of the metal foil 200 are depicted using dashed lines for simplicity and since these features are disposed below the first cover glass 300 in the view of FIG. 9. The one or more foil-glass laser bonds 202 and the (optional) foil-foil laser bond 220 are depicted using thickened, bold lines to emphasize the general structure thereof.

As described above, the use of the foil-foil laser bond 220 may depend on the configuration of the metal foil 200. In embodiments, as shown in FIG. 9, the foil-foil laser bond 220 can be used to join the first foil portion 204 and the second foil portion 212 together when the metal foil 200 is configured as two or more distinct bodies (e.g., one body comprising the first foil portion 204 and at least one other body comprising the second foil portion 212) that can be mechanically connected together to hermetically seal the glass structure 100 after the first foil portion 204 and the second foil portion 212 are connected to the glass structure 100 via the one or more foil-glass laser bonds 202. The foil-foil laser bond 220 may be optional if the metal foil is configured as a monolithic body such that the first foil portion 204 and the second foil portion 212 are integral features of the monolithic body and no further bonding (e.g., laser bonding or otherwise) is needed to hermetically seal the glass structure 100 after the first foil portion 204 and the second foil portion 212 are connected to the glass structure 100 via the one or more foil-glass laser bonds 202.

As shown in FIG. 9, each of the one or more foil-glass laser bonds 202 (e.g., the first foil-glass laser bond 202a, the second foil-glass laser bond 202b, and the third foil-glass laser bond 202c) extends along a respective closed contour 236 that encircles the central region 136 of the glass structure 100. The foil-foil laser bond 220 similarly extends along a closed contour 238 that encircles the central region 136 of the glass structure 100. As used herein, a “closed contour” means that the laser bond follows a continuous (e.g., unbroken) path in which the linear segments and/or curves that define the shape of the path are connected or meet such that the path starts and ends at the same point. In embodiments, the first foil-glass laser bond 202a extends along a first closed contour 236a, the second foil-glass laser bond 202b extends along a second closed contour 236b, and the third foil-glass laser bond 202c extends along a third closed contour 236c.

Referring now to FIGS. 1 and 9, although the first foil-glass laser bond 202a, the second foil-glass laser bond 202b, and the third foil-glass laser bond 202c are spaced from one another in the thickness direction as shown in the cross section of FIG. 1, these laser bonds are depicted extending along a single closed contour (e.g., close contour associated with reference numerals 236, 236a, 236b, 236c) in the top view of FIG. 9 since these laser bonds are all substantially laterally aligned with one another as shown in FIG. 1. The foil-foil laser bond 220 and the closed contour 238 along which the foil-foil laser bond 220 extends are disposed laterally outwardly from the first, second, and third foil-glass laser bonds 202a, 202b, 202c and the first, second, and third closed contours 236a, 236b, 236c along which the first, second, and third foil-glass laser bonds 202a, 202b, 202c, respectively, extend.

In embodiments, the one or more foil-glass laser bonds 202 are formed via one or more welding steps in which the laser beam is traversed along a respective contact location between the metal foil 200 and the glass material to facilitate a line bond between the metal foil 200 and the glass material. For example, the laser beam can be traversed along the first contact location to facilitate a line bond (e.g., the first foil-glass laser bond 202a along the first closed contour 236a) between the first major surface 108 of the glass structure 100 and the first foil surface 208 of the first foil portion 204 of the metal foil 200. In embodiments, the first foil-glass laser bond 202a can have a first bond width t₁ greater than or equal to 5 μm and less than or equal to 100 μm. Furthermore, the laser beam can circumscribe the inner periphery 228 of the first foil portion 204 such that the first foil-glass laser bond 202a between the first major surface 108 and the first foil surface 208 circumscribes the inner periphery 228 of the first foil portion 204.

The laser beam can also be traversed along the second contact location to facilitate a line bond (e.g., the second foil-glass laser bond 202b along the second closed contour 236b) between the second major surface 116 of the glass structure 100 and the second foil surface 216 of the second foil portion 212 of the metal foil 200. In embodiments, the second foil-glass laser bond 202b can have a second bond width 12 greater than or equal to 5 μm and less than or equal to 100 μm. Furthermore, the laser beam can circumscribe the inner periphery 228 of the second foil portion 212 such that the second foil-glass laser bond 202b between the second major surface 116 and the second foil surface 216 circumscribes the inner periphery 228 of the second foil portion 212.

The laser beam can also be traversed along the third contact location to facilitate a line bond (e.g., the third foil-glass laser bond 202c along the third closed contour 236c) between the first cover glass 300 and the third foil surface 224 of the second foil portion 212 of the metal foil 200. In embodiments, the third foil-glass laser bond 202c can have a third bond width t₃ greater than or equal to 5 μm and less than or equal to 100 μm. Furthermore, the laser beam can circumscribe the inner periphery 228 of the second foil portion 212 such that the third foil-glass laser bond 202c between the first cover glass 300 and the third foil surface 224 circumscribes the inner periphery 228 of the second foil portion 212.

In embodiments, the foil-foil laser bond 220 is formed via one or more welding steps in which the laser beam is traversed along a contact location between different portions of the metal foil 200 to facilitate a line bond between the different portions of the metal foil 200. For example, in embodiments in which the metal foil 200 is configured as two or more distinct bodies (e.g., one body comprising the first foil portion 204 and at least one other body comprising the second foil portion 212), the laser beam can be traversed along a contact location between portions of the first foil portion 204 and the second foil portion 212 (e.g., not connected to the glass structure 100) to facilitate a line bond (e.g., the foil-foil laser bond 220 along the closed contour 238) between the first foil portion 204 and the second foil portion 212 of the metal foil 200. In embodiments, the foil-foil laser bond 220 can have a bond width t greater than or equal to 5 μm and less than or equal to 100 μm. Furthermore, the laser beam can circumscribe the inner periphery 228 of the first foil portion 204 and/or the second foil portion 212 and the periphery 124 of the glass structure 100 such that the foil-foil laser bond 220 between the first foil portion 204 and the second foil portion 212 circumscribes the inner periphery 228 of the first foil portion 204 and/or the second foil portion 212 and the periphery 124 of the glass structure 100.

Examples of fixtures and processes (including laser parameters) that can be used to form the one or more foil-glass laser bonds 202 and/or the foil-foil laser bond 220 so as to hermetically seal the glass structure 100 and connect the glass structure 100 to the first cover glass 300 are described in U.S. Patent Application Pub. No. 2024/0058895, which is incorporated by reference herein in its entirety.

The processes used to form the one or more foil-glass laser bonds 202 disclosed herein utilize lower energy lasers to minimize related thermal defects in regions proximate the bonds by reducing a maximum bond depth. The maximum bond depth may refer to the distance in which the metal foil penetrates the glass substrate during the welding step. In such embodiments, a reduced maximum bond depth of less than or equal to 600 μm can be achieved. In embodiments, the maximum bond depth can be less than or equal to 10 μm. By minimizing the maximum bond depth, laser defects within the bond location can be minimized. Additionally, minimizing the maximum bond depth can minimize the amount of material required to achieve the desired bond between the metal foil and the glass substrate, while also increasing the adaptability of the glass structure.

Referring now to FIGS. 2 and 7, a laser-bonded assembly 10b is shown in a second configuration. The laser-bonded assembly 10b in the second configuration can be interchangeably referred to as the second laser-bonded assembly 10b for case of description though such reference should not be considered to limit the scope of the disclosure. The second laser-bonded assembly 10b comprises some elements that are the same as or substantially similar to the elements of the first laser-bonded assembly 10a. The elements of the second laser-bonded assembly 10b that are the same as or substantially similar to the elements of the first laser-bonded assembly 10a (e.g., in terms of structure, materials, properties, fabrication processes, etc.) are identified using like reference numerals. New or different elements of the second laser-bonded assembly 10b are identified using unique reference numerals.

The second laser-bonded assembly 10b comprises the glass structure 100, the metal foil 200, and the first cover glass 300 as described hereinabove. The glass structure 100 is configured to be hermetically sealed (e.g., by the metal foil 200). The glass structure 100 includes the first glass substrate 104 and the second glass substrate 112 that define the first major surface 108 and the second major surface 116, respectively, of the glass structure 100. The glass structure 100 of the second laser-bonded-assembly 10b optionally includes the fill layer(s) 118 as described above with reference to the first laser-bonded assembly 10a. The glass structure 100 further includes the peripheral edge 120 that extends between the first major surface 108 and the second major surface 112 about the periphery 124 of the glass structure 100.

The metal foil 200 of the second laser-bonded assembly 10b is configured to encircle the peripheral edge 120 about the periphery 124 of the glass structure 100. The metal foil 200 is connected to the glass structure 100 via the one or more foil-glass laser bonds 202. For example, the metal foil 200 comprises the first foil portion 204 with the first foil surface 208 that is connected to the first major surface 108 of the first glass substrate 104 at the first contact location via the first foil-glass laser bond 202a. The metal foil 200 also comprises the second foil portion 212 with the second foil surface 216 that is connected to the second major surface 116 of the second glass substrate 112 at the second contact location via the second foil-glass laser bond 202b. The metal foil 200 can be a monolithic body that may or may not comprise the foil-foil laser bond 220. The metal foil 200 can comprise separate, distinct bodies (e.g., one body comprising the first foil portion 204 and at least one other body comprising the second foil portion 212) that can be mechanically connected together via the foil-foil laser bond 220 to hermetically seal the glass structure 100 after the first foil portion 204 and the second foil portion 212 are connected to the glass structure 100 via the one or more foil-glass laser bonds 202.

The first cover glass 300 of the second laser-bonded assembly 10b is connected to one or more of the glass structure 100 and the metal foil 200. For example, the second foil portion 212 with the third foil surface 224 is connected to the first cover glass 300 at the third contact location via the third foil-glass laser bond 202c. The third foil surface 224 of the second foil portion 212 can be additionally or alternatively connected to the first cover glass 300 at the third contact location via optically clear adhesive (OCA).

Referring still to FIGS. 2 and 7, the second laser-bonded assembly 10b further comprises a frame 420 that is disposed adjacent the first cover glass 300. As best shown in FIG. 2, the glass structure 100 and the metal foil 200 are at least partially surrounded by the frame 420 and the first cover glass 300. The frame 420 is preferably formed from metal, but the frame 420 can be formed from other materials, such as plastic, reinforced plastic (e.g., carbon-fiber filled, glass-filled, etc.), or similarly rigid and impact-resistant materials that can support the first cover glass 300 when connected to the frame 420. In embodiments, the first cover glass 300 is mechanically attached to the frame 420. The first cover glass 300 can be mechanically attached to the frame 420 in a manner similar to how the cover glass is connected to the metal frames of cellular phones. Such a mechanical attachment can handle the stresses and impacts on the first cover glass 300. In embodiments, the first cover glass 300 is connected to the glass structure 100 and/or the metal foil 200 (e.g., forming a sub-assembly comprising the glass structure 100, the metal foil 200, and the first cover glass 300) before the first cover glass 300 is mechanically attached to the frame 420.

The second laser-bonded assembly 10b further comprises a second cover glass 320 disposed adjacent the frame 420 and opposite the first cover glass 300 such that the glass structure 100 and the metal foil 200 are disposed between the first cover glass 300 and the second cover glass 320. As best shown in FIG. 2, the first foil portion 204 of the metal foil 200 is configured to connect to the second cover glass 320 at a fourth contact location. In embodiments, the first foil portion 204 comprises a fourth foil surface 240 that is connected to the second cover glass 320 at the fourth contact location via a fourth foil-glass laser bond 202d of the one or more foil-glass laser bonds 202. In embodiments, the fourth foil surface 240 of the first foil portion 204 is additionally or alternatively connected to the second cover glass 320 at the fourth contact location via optically clear adhesive (OCA). In embodiments, the second cover glass 320 can be the same as or substantially similar to the first cover glass 300 in terms of structure, materials, and/or properties or the second cover glass 320 can be different than the first cover glass 300 in terms of structure, materials, and/or properties. An advantage of the second laser-bonded assembly 10b comprising the first cover glass 300 and the second cover glass 320 is having scratch resistance and protection both sides of the assembly.

Referring now to FIGS. 1 and 2, the frame 420 of the second laser-bonded assembly 10b can have structural differences compared to the frame 400 of the first laser-bonded assembly 10a. For example, the frame 420 of the second laser-bonded assembly 10b can be thinner than the frame 400 of the first laser-bonded assembly (e.g., relative a direction perpendicular to the first and second major surfaces 108, 116 of the glass structure 100) since the second cover glass 320 of the second laser-bonded assembly 10b is configured to additionally support and/or surround (e.g., protect) the glass structure 100 and the metal foil 200. In embodiments, the frame 420 of the second laser-bonded assembly 10b can be the same as or substantially similar to the frame 400 of the first laser-bonded assembly 10a in terms of materials and/or properties or the frame 420 can be different than the frame 400 in terms of materials and/or properties.

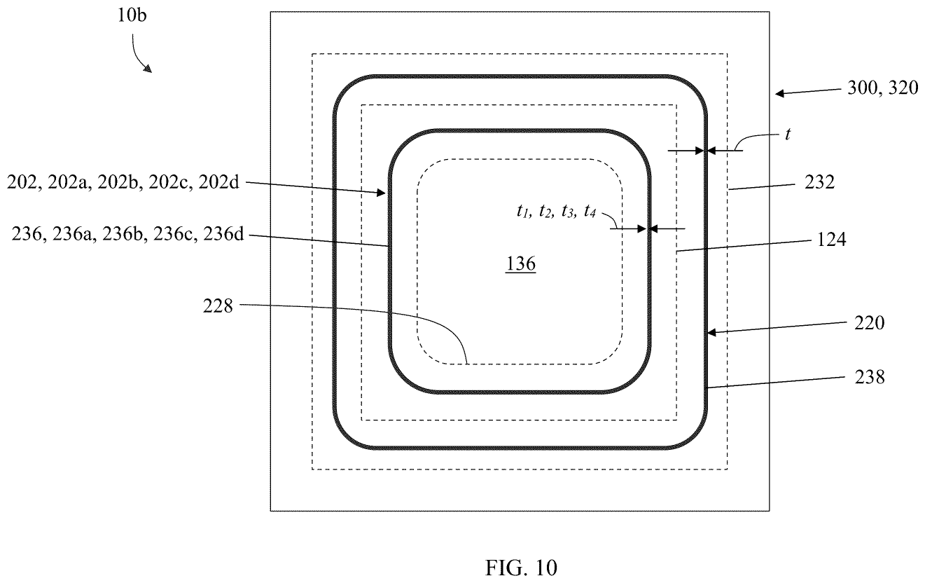

Referring now to FIG. 10, a simplified schematic top view of the second laser-bonded assembly 10b of FIG. 2 is shown to illustrate aspects of the one or more foil-glass laser bonds 202 and the (optional) foil-foil laser bond 220. The view of FIG. 10 is simplified in that most features of the second laser-bonded assembly 10b are shown fully transparent and the frame 420 is not shown. The periphery 124 of the glass structure 100, the inner periphery 228 of the metal foil 200, and the outer periphery 232 of the metal foil 200 are depicted using dashed lines for simplicity and since these features are disposed between the first cover glass 300 and the second cover glass 320 in the view of FIG. 10. In embodiments, respective (outer) peripheries of the first cover glass 300 and the second cover glass 320 can have the same shape and be aligned, as shown in FIG. 10, or the peripheries can have different shapes and/or different alignments. The one or more foil-glass laser bonds 202 and the (optional) foil-foil laser bond 220 are depicted using thickened, bold lines to emphasize the general structure thereof.

As shown in FIG. 10, the first foil-glass laser bond 202a extends along the first closed contour 236a, the second foil-glass laser bond 202b extends along the second closed contour 236b, the third foil-glass laser bond 202c extends along the third closed contour 236c, and the foil-foil laser bond 220 extends along the closed contour 238. In embodiments, the fourth foil-glass laser bond 202d of the second laser-bonded assembly 10b similarly extends along a fourth closed contour 236d.

Referring now to FIGS. 2 and 10, although the first foil-glass laser bond 202a, the second foil-glass laser bond 202b, the third foil-glass laser bond 202c, and the fourth foil-glass laser bond 202d are spaced from one another in the thickness direction as shown in the cross section of FIG. 2, these laser bonds are depicted extending along a single closed contour (e.g., closed contour associated with reference numerals 236, 236a, 236b, 236c, 236d) in the top view of FIG. 10 since these laser bonds are all substantially laterally aligned with one another as shown in FIG. 2. The foil-foil laser bond 220 and the closed contour 238 along which the foil-foil laser bond 220 extends are disposed laterally outwardly from the first, second, third, and fourth foil-glass laser bonds 202a, 202b, 202c, 202d and the first, second, third, and fourth closed contours 236a, 236b, 236c, 236d along which the first, second, third, and fourth foil-glass laser bonds 202a, 202b, 202c, 202d, respectively, extend.

In embodiments, the first foil-glass laser bond 202a, the second foil-glass laser bond 202b, the third foil-glass laser bond 202c, and the (optional) foil-foil laser bond 220 of the second laser-bonded assembly 10b can be formed using the same or substantially same laser beam welding steps used to form the corresponding laser bonds of the first laser-bonded assembly 10a. Additionally, the laser beam can also be traversed along the fourth contact location to facilitate a line bond (e.g., the fourth foil-glass laser bond 202d along the fourth closed contour 236d) between the second cover glass 320 and the fourth foil surface 240 of the first foil portion 204 of the metal foil 200. In embodiments, the fourth foil-glass laser bond 202d can have a fourth bond width t greater than or equal to 5 μm and less than or equal to 100 μm. Furthermore, the laser beam can circumscribe the inner periphery 228 of the first foil portion 204 such that the fourth foil-glass laser bond 202d between the second cover glass 320 and the fourth foil surface 240 circumscribes the inner periphery 228 of the first foil portion 204.

The fixtures and processes (including laser parameters) used to form the one or more foil-glass laser bonds 202 and/or the foil-foil laser bond 220 so as to hermetically seal the glass structure 100 of the first laser-bonded assembly 10a and connect the glass structure 100 to the first cover glass 300 of the first laser-bonded assembly 10a can be used to form the one or more foil-glass laser bonds 202 and/or the foil-foil laser bond 220 so as to hermetically seal the glass structure 100 of the second laser-bonded assembly 10b and connect the glass structure 100 to the first cover glass 300 and the second cover glass 320 of the second laser-bonded assembly 10b.

Referring now to FIGS. 3 and 8, a laser-bonded assembly 10c is shown in a third configuration. The laser-bonded assembly 10c in the third configuration can be interchangeably referred to as the third laser-bonded assembly 10c for case of description though such reference should not be considered to limit the scope of the disclosure. The third laser-bonded assembly 10c comprises some elements that are the same as or substantially similar to the elements of the first laser-bonded assembly 10a and/or the second laser-bonded assembly 10b. The elements of the third laser-bonded assembly 10c that are the same as or substantially similar to the elements of the first laser-bonded assembly 10a and/or the second laser-bonded assembly 10b (e.g., in terms of structure, materials, properties, fabrication processes, etc.) are identified using like reference numerals. New or different elements of the third laser-bonded assembly 10c are identified using unique reference numerals.

The third laser-bonded assembly 10c comprises the glass structure 100, the first cover glass 300, the second cover glass 320, and the frame 420 as described hereinabove. In embodiments, the glass structure 100 of the third laser-bonded assembly 10c is configured to be hermetically sealed by one or more of the first cover glass 300, the second cover glass 320, and a metal foil 250. The glass structure 100 includes the first glass substrate 104 and the second glass substrate 112 that define the first major surface 108 and the second major surface 116, respectively, of the glass structure 100. The glass structure 100 of the third laser-bonded-assembly 10c optionally includes the fill layer(s) 118 as described above with reference to the first laser-bonded assembly 10a and the second laser-bonded assembly 10b. The glass structure 100 further includes the peripheral edge 120 that extends between the first major surface 108 and the second major surface 112 about the periphery 124 of the glass structure 100.

The metal foil 250 of the third laser-bonded assembly 10c is configured to encircle the peripheral edge 120 about the periphery 124 of the glass structure 100. The metal foil 250 is connected to the glass structure 100 via one or more foil-glass laser bonds 202 that are similar to the one or more foil-glass laser bonds 202 described with reference to the first laser-bonded assembly 10a and the second laser-bonded assembly 10b. The metal foil 250 of the third laser-bonded assembly 10c has a different configuration than the metal foil 200 of the first laser-bonded assembly 10a and the second laser-bonded assembly 10b. As shown in FIGS. 3 and 8, the metal foil 250 of the third laser-bonded assembly 10c has a bucket- or step-shaped three-dimensional configuration. The bucket-shape of the metal foil 250 of the third laser-bonded assembly 10c can have certain fabrication efficiencies as described later in this disclosure.

Referring still to FIGS. 3 and 8, the metal foil 250 comprises a first foil portion 204 that extends towards the glass structure 100 and connects to the first major surface 108 at a first contact location. In embodiments, the first foil portion 204 comprises a first foil surface 208 that is connected to the first major surface 108 at the first contact location via a first foil-glass laser bond 202a of the one or more foil-glass laser bonds 202. The metal foil 250 further comprises a second foil portion 212 that extends away from the glass structure 100 and connects to the first cover glass 300 at a second contact location. In embodiments, the second foil portion 212 comprises a second foil surface 216 (FIG. 8) that is connected to the first cover glass 300 at the second contact location via a second foil-glass laser bond 202b of the one or more foil-glass laser bonds 202.

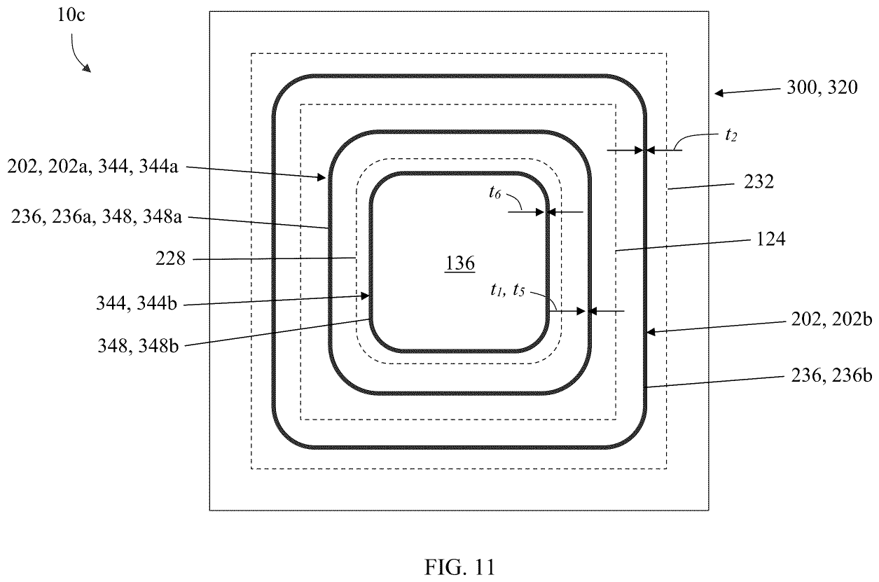

In embodiments, the metal foil 250 of the third laser-bonded assembly 10c comprises an inner periphery 228 (e.g., innermost perimeter) and an outer periphery 232 (e.g., outermost perimeter). The glass structure 100 comprises the central region 136 (FIG. 11) through which one or more of the first glass substrate 104, the second glass substrate 112, and the (optional) fill layer 118 can interact (e.g., directly and/or indirectly) with the external environment surrounding the third laser-bonded assembly 10c. In embodiments, the inner periphery 228 of the metal foil 250 encircles at least a portion of the central region 136 of the glass structure 100 so as to expose (e.g., not cover) the central region 136. In embodiments, a distal end of the first foil portion 204 of the metal foil 250 (e.g., overlapping the glass structure 100) defines the inner periphery 228 on a first side (e.g., a bottom side) of the third laser-bonded assembly 10c. In embodiments, a distal end of the second foil portion 212 (e.g., spaced farthest away from the glass structure 100) defines the outer periphery 232 on a second side (e.g., a top side) of the third laser-bonded assembly 10c. In embodiments, the first foil portion 204 and the second foil portion 212 can be integrally connected via a middle foil portion of the metal foil 250. In embodiments, the middle foil portion extents substantially in parallel with the peripheral edge 120 of the glass structure 100.

In embodiments, the first foil portion 204 and the second foil portion 212 of the third laser-bonded assembly 10c can have the same or substantially similar properties (e.g., in terms of thickness, material, melting point, optical transmittance/absorbance, surface roughness (Ra), etc.) as the first foil portion 204 and the second foil portion 212 of the first laser-bonded assembly 10a and/or the second laser-bonded assembly 10b.

As best shown in FIG. 3, one or more of the first cover glass 300 and the second cover glass 320 of the third laser-bonded assembly 10c can be connected to the glass structure 100 via one or more glass-glass laser bonds 344. As used herein, a “glass-glass laser bond” refers to a mechanical connection that is made (directly) between a glass material (e.g., glass or glass ceramic) of a (first) component or part of the third laser-bonded assembly 10c and a glass material of at least a (second) component or part of the third laser-bonded assembly 10c and that is formed via a laser beam directed proximate a contact location between the glass materials of the (first and second) components.

In embodiments, the first cover glass 300 is connected to the second major surface 116 of the glass structure 100 (e.g., at a third contact location) via a first glass-glass laser bond 344a of the one or more glass-glass laser bonds 344. In embodiments, the second cover glass 320 is connected to the first major surface 108 of the glass structure 108 (e.g., at a fourth contact location) via a second glass-glass laser bond 344b of the one or more glass-glass laser bonds 344. In embodiments, the first cover glass 300 is additionally or alternatively connected to the second major surface 116 of the glass structure 100 at the third contact location via optically clear adhesive (OCA). In embodiments, the second cover glass 320 is additionally or alternatively connected to the first major surface 108 of the glass structure 100 at the fourth contact location via optically clear adhesive (OCA).

In embodiments, the second major surface 116 of the second glass substrate 112 substantially abuts the surface of the first cover glass 300 along which the first glass-glass laser bond 344a is formed such that the third contact location can be disposed along any portion of the second major surface 116. In embodiments, the first major surface 108 of the first glass substrate 104 substantially abuts the surface of the second cover glass 320 along which the second glass-glass laser bond 344b is formed such that the fourth contact location can be disposed along any portion of the first major surface 108.

Referring still to FIG. 3, the first cover glass 300 and the second cover glass 320 are disposed adjacent the frame 420 on opposite sides thereof such that the glass structure 100 and the metal foil 250 are disposed between the first cover glass 300 and the second cover glass 320. In embodiments, the first cover glass 300 and the second cover glass 320 of the third laser-bonded assembly 10c can be mechanically attached to the frame 420 in a manner similar to how the first cover glass 300 and the second cover glass 320 of the second laser-bonded assembly 10b are mechanically attached to the frame 420.

Referring now to FIG. 11, a simplified schematic top view of the third laser-bonded assembly 10c of FIG. 3 is shown to illustrate aspects of the one or more foil-glass laser bonds 202 and the one or more glass-glass laser bonds 344. The view of FIG. 11 is simplified in that most features of the third laser-bonded assembly 10c are shown fully transparent and the frame 420 is not shown. The periphery 124 of the glass structure 100, the inner periphery 228 of the metal foil 250, and the outer periphery 232 of the metal foil 250 are depicted using dashed lines for simplicity and since these features are disposed below the first cover glass 300 in the view of FIG. 11. The one or more foil-glass laser bonds 202 and the one or more glass-glass laser bonds 344 are depicted using thickened, bold lines to emphasize the general structure thereof.

As shown in FIG. 11, each of the one or more foil-glass laser bonds 202 (e.g., the first foil-glass laser bond 202a and the second foil-glass laser bond 202b) of the third laser-bonded assembly 10c extends along a respective closed contour 236 that encircles the central region 136 of the glass structure 100. Similarly, each of the one or more glass-glass laser bonds 344 of the third laser-bonded assembly 10c extends along a closed contour 348 that encircles the central region 136 of the glass structure 100. In embodiments, the first foil-glass laser bond 202a extends along a first closed contour 236a and the second foil-glass laser bond 202b extends along a second closed contour 236b. In embodiments, the first glass-glass laser bond 344a extends along a first closed contour 348a and the second glass-glass laser bond 344b extends along a second closed contour 348b.

Referring now to FIGS. 3 and 11, although the first foil-glass laser bond 202a and the first glass-glass laser bond 344a are spaced from one another in the thickness direction as shown in the cross section of FIG. 3, these laser bonds are depicted extending along a single closed contour (e.g., closed contour associated with reference numerals 236, 236a, 348, 348a) in the top view of FIG. 11 since these laser bonds are all substantially laterally aligned with one another as shown in FIG. 3. The second foil-glass laser bond 202b and the second closed contour 236b along which the second foil-glass laser bond 202b extends are disposed laterally outwardly from the first foil-glass laser bond 202a and the first glass-glass laser bond 344a and the first closed contour 236a and the first closed contour 348a along which the first foil-glass laser bond 202a and the first glass-glass laser bond 344a, respectively, extend. The second glass-glass laser bond 344b and the second closed contour 348b along which the second glass-glass laser bond 344b extends are disposed laterally inwardly from the first foil-glass laser bond 202a and the first glass-glass laser bond 344a and the first closed contour 236a and the first closed contour 348a along which the first foil-glass laser bond 202a and the first glass-glass laser bond 344a, respectively, extend.

In embodiments, the first foil-glass laser bond 202a and the second foil-glass laser bond 202b of the third laser-bonded assembly 10c can be formed using the same or substantially same laser beam welding steps used to form the corresponding laser bonds of the first laser-bonded assembly 10a and the second laser-bonded assembly 10b. In embodiments, the one or more glass-glass laser bonds 344 are formed via one or more welding steps in which the laser beam is traversed along a respective contact location between the glass materials of different components or parts of the third laser-bonded assembly 10c to facilitate a line bond between the glass materials.

Additionally, the laser beam can be traversed along the third contact location to facilitate a line bond (e.g., the first glass-glass laser bond 344a along the first closed contour 348a) between the first cover glass 300 and the second major surface 116 of the glass structure 100. In embodiments, the first glass-glass laser bond 344a can have a fifth bond width 15 greater than or equal to 5 μm and less than or equal to 100 μm. Furthermore, the laser beam can circumscribe the inner periphery 228 of the metal foil 250 such that the first glass-glass laser bond 344a between the first cover glass 300 and the second major surface 116 circumscribes the inner periphery 228 of the metal foil 250.

The laser beam can be traversed along the fourth contact location to facilitate a line bond (e.g., the second glass-glass laser bond 344b along the second closed contour 348b) between the second cover glass 320 and the first major surface 108 of the glass structure 100. In embodiments, the second glass-glass laser bond 344b can have a sixth bond width 16 greater than or equal to 5 μm and less than or equal to 100 μm. Furthermore, the laser beam can be traversed laterally inwardly from the inner periphery 228 of the metal foil 250 such that the second glass-glass laser bond 344b between the second cover glass 320 and the first major surface 108 is disposed laterally inwardly from the inner periphery 228 of the metal foil 250.

The fixtures and processes (including laser parameters) used to form the one or more foil-glass laser bonds 202 and/or the foil-foil laser bond 220 so as to hermetically seal the glass structure 100 of the second laser-bonded assembly 10b and connect the glass structure 100 to the first cover glass 300 and/or the second cover glass 320 of the second laser-bonded assembly 10b can be used to form the one or more foil-glass laser bonds 202 and/or the one or more glass-glass laser bonds 344 so as to hermetically seal the glass structure 100 of the third laser-bonded assembly 10c and connect the glass structure 100 to the first cover glass 300 and the second cover glass 320 of the third laser-bonded assembly 10c.

In an exemplary embodiment, the positions of the one or more foil-glass laser bonds 202 and the one or more glass-glass laser bonds 344 of the third laser-bonded assembly 10c shown in FIGS. 3 and 11 enable the one or more foil-glass laser bonds 202 and the one or more glass-glass laser bonds 344 to be formed in a single laser beam welding step without having to unload, flip, re-load, and re-align the glass structure 100 as may be needed in other configurations. The single laser beam welding step can be used be used in configurations of the laser-bonded assembly in which the second cover glass 320 and the second glass-glass laser bond 344b are omitted from the third laser-bonded assembly 10c.

Referring now to FIG. 4, a laser-bonded assembly 10d is shown in a fourth configuration. The laser-bonded assembly 10a in the fourth configuration can be interchangeably referred to as the fourth laser-bonded assembly 10d for case of description though such reference should not be considered to limit the scope of the disclosure. The fourth laser-bonded assembly 10d comprises some elements that are the same as or substantially similar to the elements of the first, second, and/or third laser-bonded assemblies 10a, 10b, 10c. The elements of the fourth laser-bonded assembly 10d that are the same as or substantially similar to the elements of the first, second, and/or third laser-bonded assemblies 10a, 10b, 10c (e.g., in terms of structure, materials, properties, fabrication processes, etc.) are identified using like reference numerals. New or different elements of the fourth laser-bonded assembly 10d are identified using unique reference numerals.

The fourth laser-bonded assembly 10d comprises the glass structure 100 as described hereinabove. The glass structure 100 is configured to be hermetically sealed (e.g., by a polymer seal alone or in combination with other components). The glass structure 100 includes the first glass substrate 104 and the second glass substrate 112 that define the first major surface 108 and the second major surface 116, respectively, of the glass structure 100. The glass structure 100 of the fourth laser-bonded-assembly 10b optionally includes the fill layer(s) 118 as described above with reference to the first, second, and third laser-bonded assemblies 10a, 10b, 10c. The glass structure 100 further includes the peripheral edge 120 that extends between the first major surface 108 and the second major surface 112 about the periphery 124 of the glass structure 100.

Referring still to FIG. 4, the fourth laser-bonded assembly 10d further comprises a polymer seal 500 that is configured to encircle the peripheral edge 120 about the periphery 124 of the glass structure 100. As used herein, the terms “encircle,” “encircles,” “encircling”, or the like mean that the polymer seal 500 is shaped and/or positioned to encompass, surround, and/or cover an entirety of the peripheral edge 120 (e.g., the surfaces that form or define the peripheral edge) when viewed in a direction parallel to the first major surface 108 and the second major surface 116 from a position laterally outside or external the glass structure 100 and the polymer seal 500, such as illustrated by the arrow 504 in FIG. 4. In embodiments, the polymer seal 500 can comprise any polymer or polymer-based material that enables the geometry, properties, attributes, performance, and/or functions described throughout the present disclosure with respect to the polymer seal 500.

The fourth laser-bonded assembly 10d further comprises a first cover glass 350 and a second cover glass 370. The first cover glass 350 comprises a first inner surface 352 and a first outer surface 354 that faces opposite the first inner surface 352. The second cover glass 370 comprises a second inner surface 372 and a second outer surface 374 that faces opposite the first inner surface 372. The first cover glass 350 is disposed adjacent the polymer seal 500 and the glass structure 100 on a first side (e.g., a top side) of the fourth laser-bonded assembly 10d. The second cover glass 370 is disposed adjacent the polymer seal 500 and the glass structure 100 on a second side (e.g., a bottom side) of the fourth laser-bonded assembly 10d opposite the first cover glass 350. The glass structure 100 and the polymer seal 500 are disposed in a cavity 378 between and/or surrounded by the first cover glass 350 and the second cover glass 370.

In embodiments, the first cover glass 350 of the fourth laser-bonded assembly 10d can be the same as or substantially similar to the first cover glass 300 of the third laser-bonded assembly 10c in terms of materials and/or properties. The second cover glass 370 of the fourth laser-bonded assembly 10d can be the same as or substantially similar to the first cover glass 350 of the fourth laser-bonded assembly 10d in terms of structure, materials, and/or properties or the second cover glass 370 can be different than the first cover glass 350 in terms of structure, materials, and/or properties.

In embodiments, at least one of the first cover glass 350 and the second cover glass 370 comprises a peripheral wall 382 that extends towards the other of the first cover glass 350 and the second cover glass 370 about a periphery thereof and at least partially defines the cavity 378. In the embodiment shown in FIG. 4, the first cover glass 350 comprises the peripheral wall 382 that extends toward the second cover glass 370. In embodiments, the second cover glass 370 can comprise the peripheral wall (not shown) that extends towards the first cover glass 350. In embodiments, each of the of the first cover glass 350 and the second cover glass 370 can comprise a respective peripheral wall (or peripheral wall portion) that extends towards the other of the of the first cover glass 350 and the second cover glass 370. For example, the first cover glass 350 can comprise a first peripheral wall that extends towards the second cover glass 370 and the second cover glass 370 can comprise a second peripheral wall that extends towards the first cover glass 350.

In embodiments comprising the first peripheral wall and the second peripheral wall, the first peripheral wall can have a length (e.g., in the direction that the peripheral wall extends) that is the same as or substantially similar to a length of the second peripheral wall. In embodiments comprising the first peripheral wall and the second peripheral wall, the first peripheral wall can have a length (e.g., in the direction that the peripheral wall extends) that is different than a length of the second peripheral wall.

In embodiments, the second cover glass 370 is connected to one or more of the glass structure 100 and the first cover glass 350 via one or more glass-glass laser bonds 394. As used herein, a “glass-glass laser bond” refers to a mechanical connection that is made (directly) between a glass material (e.g., glass or glass ceramic) of a (first) component or part of the fourth laser-bonded assembly 10d and a glass material of at least a (second) component or part of the fourth laser-bonded assembly 10d and that is formed via a laser beam directed proximate a contact location between the glass materials of the (first and second) components.

In embodiments, the first cover glass 350 and the second cover glass 370 are connected to one another at the peripheral wall 382 via a first glass-glass laser bond 394a of the one or more glass-glass laser bonds 394. For example, as shown in FIG. 4, the first cover glass 350 and the second cover glass 370 can be connected via the first glass-glass laser bond 394a at a first contact location between an end surface 386 of the peripheral wall 382 of the first cover glass 350 and the second inner surface 372 of the second cover glass 370. In embodiments in which the second cover glass 370 has the peripheral wall (not shown) and the first cover glass 350 does not have a peripheral wall (not shown), the first cover glass 350 and the second cover glass 370 can be connected via the first glass-glass laser bond at a first contact location between an end surface of the peripheral wall of the second cover glass 370 and the second inner surface 352 of the first cover glass 350. In embodiments in which each of the first cover glass 350 and the second cover glass 370 has the peripheral wall (not shown), the first cover glass 350 and the second cover glass 370 can be connected via the first glass-glass laser bond at a first contact location between an end surface of the peripheral wall of first cover glass 350 and an end surface of the peripheral wall of the second cover glass 370.

In embodiments, the second cover glass 370 is connected to the first major surface 108 of the glass structure 100 (e.g., at a second contact location) via a second glass-glass laser bond 394b of the one or more glass-glass laser bonds 394. In embodiments, the first cover glass 350 is connected to the second major surface 116 of the glass structure 100 (e.g., at a third contact location) via a third glass-glass laser bond 394c of the one or more glass-glass laser bonds 394. In embodiments, the second cover glass 370 is additionally or alternatively connected to the first major surface 108 of the glass structure 100 at the second contact location via optically clear adhesive (OCA). In embodiments, the first cover glass 350 is additionally or alternatively connected to the second major surface 116 of the glass structure 100 at the third contact location via optically clear adhesive (OCA).

In embodiments, the first major surface 108 of the first glass substrate 104 substantially abuts the second inner surface 372 of the second cover glass 370 along which the second glass-glass laser bond 394b is formed such that the second contact location can be disposed along any portion of the first major surface 108. In embodiments, the second major surface 116 of the second glass substrate 112 substantially abuts the first inner surface 352 of the first cover glass 350 along which the first glass-glass laser bond 344a is formed such that the third contact location can be disposed along any portion of the second major surface 116.

Referring still to FIG. 4, the first cover glass 350 and the second cover glass 370 are disposed adjacent the glass structure 100 and the polymer seal 500 on opposite sides thereof such that the glass structure 100 and the polymer seal 500 are disposed between the first cover glass 350 and the second cover glass 370. In embodiments, the polymer seal 500 abuts the peripheral edge 120 of the glass structure 100 about the periphery 124 thereof. For example, the polymer seal 500 can be disposed directly against the peripheral edge 120 of the glass structure 100 during fabrication of the fourth laser-bonded assembly 10d.

In embodiments, the polymer seal 500 can be configured as a flexible or semi-flexible, open-centered member configured to be one or more of stretched and positioned onto the periphery 124 of the glass structure 100. In such embodiments, the polymer seal 500 can have any shape (e.g., circular, rectangular, triangular, freeform, etc.) that is configured to conform to the periphery 124 of the glass structure 100 when placed thereon. In embodiments, the polymer seal 500 can be configured as a rigid, semi-rigid, or flexible member that is positioned, applied, and/or deposited onto and proximate the peripheral edge 120 about the entire periphery 124 of the glass structure 100. In embodiments, a laterally inwardly facing side 508 of the polymer seal 500 is configured to abut the peripheral edge 120 of the glass structure 100. In embodiments, a laterally outwardly facing side 512 of the polymer seal 500 (e.g., facing away from the laterally inwardly facing side 508) is exposed within a portion of the cavity 378 that is not occupied by the glass structure 100 or other features of fourth laser-bonded assembly 10d.

In embodiments, upper and lower sides of the polymer seal 500 abut opposed inner surfaces of the first and second cover glasses. For example, an upper side 516 of the polymer seal 500 abuts the first inner surface 352 of the first cover glass 350 and a lower side 520 of the second inner surface 372 of the second cover glass 370 when the first cover glass 350 and the second cover glass 370 are connected via the first glass-glass laser bond 349a. In embodiments, during the fabrication of the fourth laser-bonded assembly 10d, the polymer seal 500 can have a first thickness between the upper side 516 and the lower side 520 in the thickness direction that is larger than the thickness of the glass structure 100 and its peripheral edge 120 in the thickness direction such that the polymer seal 500 is compressed to a second thickness (e.g., smaller than the first thickness) between the first cover glass 350 and the second cover glass 370 when the first and second cover glasses 350, 370 are connected together via the first glass-glass laser bond 394a.

Referring now to FIG. 12, a simplified schematic top view of the fourth laser-bonded assembly 10d of FIG. 4 is shown to illustrate aspects of the one or more glass-glass laser bonds 394. The view of FIG. 12 is simplified in that most features of the fourth laser-bonded assembly 10d are shown fully transparent. The periphery 124 of the glass structure 100, the laterally inwardly facing side 508 of the polymer seal 500 (which coincides with the periphery 124 of the glass structure 100), the laterally outwardly facing side 512 of the polymer seal 500, and an inward edge 390 of the peripheral wall 382 are depicted using dashed lines for simplicity and since these features are disposed below the first cover glass 300 in the view of FIG. 12. The one or more glass-glass laser bonds 394 are depicted using thickened, bold lines to emphasize the general structure thereof.

As shown in FIG. 12, each of the one or more glass-glass laser bonds 394 (e.g., the first glass-glass laser bond 394a, the second glass-glass laser bond 394b, and the third glass-glass laser bond 394c) of the fourth laser-bonded assembly 10d extends along a respective closed contour 396 that encircles the central region 136 of the glass structure 100. In embodiments, the first glass-glass laser bond 394a extends along a first closed contour 396a, the second glass-glass laser bond 394b extends along a second closed contour 396b, and the third glass-glass laser bond 394c extends along a third closed contour 396c.

Referring now to FIGS. 4 and 12, each of the glass-glass laser bonds 394 of the fourth laser-bonded assembly 10d is spaced laterally from one another. In embodiments, the first-glass-glass laser bond 394a (shown extending along the first closed contour 396a in FIG. 12) is disposed laterally outwardly from the second glass-glass laser bond 394b (shown extending along the second closed contour 396b in FIG. 12) and the third glass-glass laser bond 349c (shown extending along the third closed contour 396c in FIG. 12). In embodiments, the third glass-glass laser bond 394c is disposed laterally inwardly from the first glass-glass laser bond 394a and the second glass-glass laser bond 394b. In embodiments, the second glass-glass laser bond 394b is disposed between the first glass-glass laser bond 394a and the third glass-glass laser bond 394c such that the second glass-glass laser bond 394b is disposed laterally inwardly from the first glass-glass laser bond 394a. In such embodiments, the second glass-glass laser bond 394b is also disposed laterally outwardly from the third glass-glass laser bond 394c.

In embodiments, the first glass-glass laser bond 394a, the second glass-glass laser bond 394b, and the third glass-glass laser bond 394c of the fourth laser-bonded assembly 10d can be formed using the same or substantially same laser beam welding steps used to form the glass-glass laser bonds 344 of the third laser-bonded assembly 10c. For example, the one or more glass-glass laser bonds 394 are formed via one or more welding steps in which the laser beam is traversed along a respective contact location between the glass materials of different components or parts of the fourth laser-bonded assembly 10d to facilitate a line bond (e.g., the first glass-glass laser bond 394a along the first closed contour 396a, the second glass-glass laser bond 394b along the second closed contour 396b, and the third glass-glass laser bond 394c along the third closed contour 396c) between the glass materials. As shown in FIG. 12, the first glass-glass laser bond 394a can have a first bond width t₁, the second glass-glass laser bond 394b can have a second bond width t₂, and the third glass-glass laser bond 394c can have a third bond width t₃. In embodiments, each of the first, second, and third bond widths t₁, t₂, t₃, can be greater than or equal to 5 μm and less than or equal to 100 μm.

The fixtures and processes (including laser parameters) used to form the one or more foil-glass laser bonds 202, the foil-foil laser bond 220, the glass-glass laser bonds 344 so as to hermetically seal the glass structure 100 of the third laser-bonded assembly 10c and connect the glass structure 100 to the first cover glass 300 and/or the second cover glass 320 of the third laser-bonded assembly 10c can be used to form the one or more glass-glass laser bonds 394 so as to hermetically seal the glass structure 100 of the fourth laser-bonded assembly 10d and connect the glass structure 100 to the first cover glass 350 and the second cover glass 370 of the fourth laser-bonded assembly 10d.

An exemplary method for forming the fourth laser-bonded assembly 10d is described herein. The method comprises a step in which the first major surface 108 of the glass structure 100 is laser welded to the second inner surface 372 of the second cover glass 370 via the second glass-glass laser bond 394b. Next, the polymer seal 500 is disposed on the second inner surface 372 of the second cover glass 370 so as to surround the glass structure 100 (e.g., the glass structure comprising the first glass substrate 104, the second glass substrate 112, and the fill layer 118. In embodiments, the polymer seal 500 can be applied and/or installed as a single component (e.g., an O-ring), or the polymer seal 500 can be applied in liquid or semi-liquid form and then cured to a solid or semi-solid form. In embodiments in which the polymer seal 500 is configured to be applied and then cured, the first cover glass 350 is positioned on the second cover glass 370 before curing the polymer seal 500.

After curing the polymer seal 500, the method comprises a step in which the first cover glass 350 is laser welded to the second cover glass 370 via the first glass-glass laser bond 394a. In embodiments in which the thickness of the polymer seal 500 is greater than a thickness between inner surfaces of the first and second cover glasses when the first and second glasses are connected, the thickness differential causes compression on the polymer seal 500, thereby enhancing the sealing of the glass structure 100. Optionally, depending on the required integrity of the hermetic scaling of the glass structure 100, the first inner surface 352 of the first cover glass 350 can be laser welded to the second major surface 116 of the second glass substrate 112 of the glass structure via the third glass-glass laser bond 394c. In embodiments, the laser welding used to form the second glass-glass laser bond 394b and the third glass-glass laser bond 394c should be spaced far enough from the polymer seal 500 to prevent damage to the polymer seal 500 due to (high) temperature during the laser welding.

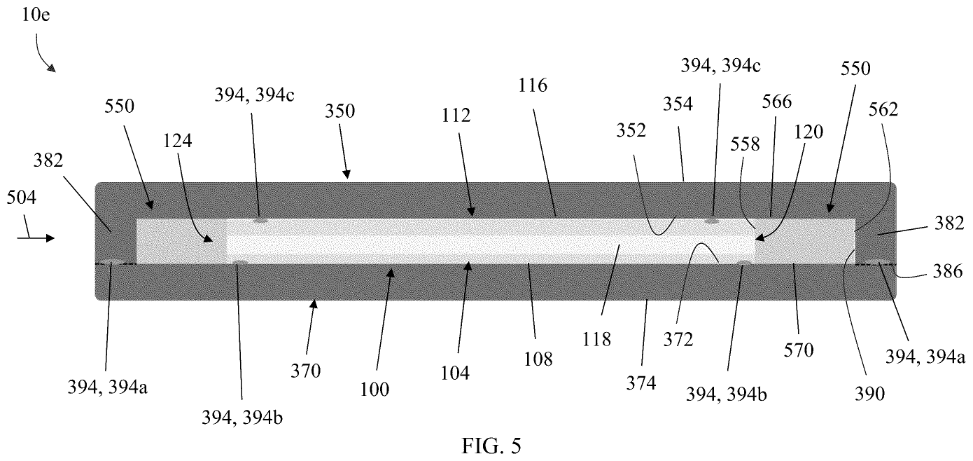

Referring now to FIG. 5, a laser-bonded assembly 10c is shown in a fifth configuration. The laser-bonded assembly 10e in the fifth configuration can be interchangeably referred to as the fifth laser-bonded assembly 10e for ease of description though such reference should not be considered to limit the scope of the disclosure. The fifth laser-bonded assembly 10c comprises many elements that are the same as or substantially similar to the elements of the fourth laser-bonded assembly 10d. The elements of the fifth laser-bonded assembly 10e that are the same as or substantially similar to the elements of the fourth laser-bonded assembly 10d (e.g., in terms of structure, materials, properties, fabrication processes, etc.) are identified using like reference numerals. New or different elements of the fifth laser-bonded assembly 10e are identified using unique reference numerals.

The fifth laser-bonded assembly 10e comprises the glass structure 100, the first cover glass 350, and the second cover glass 370 described hereinabove with reference to the fourth laser-bonded assembly 10d. In embodiments, the glass structure 100 of the fifth laser-bonded assembly 10c is configured to be hermetically sealed by one or more of the first cover glass 350, the second cover glass 370, and a polymer seal 550. The glass structure 100 includes the first glass substrate 104 and the second glass substrate 112 that define the first major surface 108 and the second major surface 116, respectively, of the glass structure 100. The glass structure 100 of the fifth laser-bonded-assembly 10e optionally includes the fill layer(s) 118 as described above with reference to the first, second, third, and fourth laser-bonded assemblies 10a, 10b, 10c, 10d. The glass structure 100 further includes the peripheral edge 120 that extends between the first major surface 108 and the second major surface 112 about the periphery 124 of the glass structure 100.

In embodiments, the polymer seal 550 of the fifth laser-bonded assembly 10e can be configured as a flexible or semi-flexible, open-centered member configured to be one or more of stretched and positioned onto the periphery 124 of the glass structure 100. In such embodiments, the polymer seal 550 can have any shape (e.g., circular, rectangular, triangular, freeform, etc.) that is configured to conform to the periphery 124 of the glass structure 100 when placed thereon. In embodiments, the polymer seal 550 can be configured as a rigid, semi-rigid, or flexible member that is positioned, applied, and/or deposited onto and proximate the peripheral edge 120 about the entire periphery 124 of the glass structure 100. In embodiments, a laterally inwardly facing side 558 of the polymer seal 550 of the fifth laser-bonded assembly 10c is configured to abut the peripheral edge 120 of the glass structure 100.

In embodiments, upper and lower sides of the polymer seal 550 of the fifth laser-bonded assembly 10c abut opposed inner surfaces of the first and second cover glasses. For example, an upper side 566 of the polymer seal 550 abuts the first inner surface 352 of the first cover glass 350 and a lower side 570 of the second inner surface 372 of the second cover glass 370 when the first cover glass 350 and the second cover glass 370 are connected via the first glass-glass laser bond 349a. In embodiments, during the fabrication of the fifth laser-bonded assembly 10c, the polymer seal 550 can have a first thickness between the upper side 566 and the lower side 570 in the thickness direction that is larger than the thickness of the glass structure 100 and its peripheral edge 120 in the thickness direction such that the polymer seal 550 is compressed to a second thickness (e.g., smaller than the first thickness) between the first cover glass 350 and the second cover glass 370 when the first and second cover glasses 350, 370 are connected together via the first glass-glass laser bond 394a.

Referring now to FIGS. 4 and 5, the polymer seal 550 of the fifth laser-bonded assembly 10c is structurally different than the polymer seal 500 of the fourth laser-bonded assembly 10d. In embodiments, as shown in FIG. 5, the polymer seal 550 of the fifth laser-bonded assembly 10c is configured to fill an entirety of the (empty) space or volume within the portion of the cavity 378 (FIG. 4) surrounded by the glass structure 100 and the inner surfaces 352, 372 of the first and second cover glasses 350, 370. For example, a laterally outwardly facing side 562 of the polymer seal 550 of the fifth laser-bonded assembly 10e is configured to abut the inward edge 390 of the peripheral wall 382. The polymer seal 500 of the fourth laser-bonded assembly 10d does not fill the cavity 378 such the (empty) space or volume remains therein, as described above with reference to FIG. 4. The polymer seal 550 of the fifth laser-bonded assembly 10c can enhance the hermetic sealing of the glass structure 100 as well as improve the (impact, shock, and/or vibrational) damping in the glass structure 100.

The polymer seal 550 of the fifth laser-bonded assembly 10e can be the same as or substantially similar to the polymer seal 500 of the fourth laser-bonded assembly 10d in terms of materials, properties, and/or fabrication processes or the polymer seal 550 can be different than the polymer seal 500 in terms of materials, properties, and/or fabrication processes.

The fixtures and processes (including laser parameters) used to form the one or more glass-glass laser bonds 394 so as to hermetically seal the glass structure 100 of the fourth laser-bonded assembly 10d and connect the glass structure 100 to the first cover glass 350 and/or the second cover glass 370 of the fourth laser-bonded assembly 10d can be used to form the one or more glass-glass laser bonds 394 so as to hermetically seal the glass structure 100 of the fifth laser-bonded assembly 10e and connect the glass structure 100 to the first cover glass 350 and/or the second cover glass 370 of the fifth laser-bonded assembly 10c.

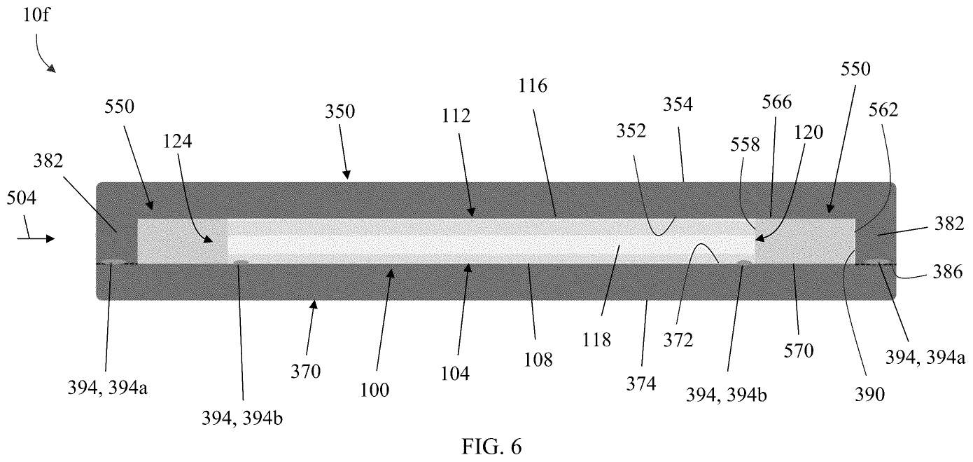

Referring now to FIG. 6, a laser-bonded assembly 10f is shown in a sixth configuration. The laser-bonded assembly 10f in the sixth configuration can be interchangeably referred to as the sixth laser-bonded assembly 10f for ease of description though such reference should not be considered to limit the scope of the disclosure. The sixth laser-bonded assembly 10f comprises many elements that are the same as or substantially similar to the elements of the fourth laser-bonded assembly 10d and the fifth laser-bonded assembly 10e. The elements of the sixth laser-bonded assembly 10f that are the same as or substantially similar to the elements of the fourth laser-bonded assembly 10d and/or the fifth laser-bonded assembly 10e (e.g., in terms of structure, materials, properties, fabrication processes, etc.) are identified using like reference numerals.

Referring now to FIGS. 5 and 6, the sixth laser-bonded assembly 10f is substantially similar to the fifth laser-bonded assembly 10e except that the third glass-glass laser bond 394c between the first cover glass 350 and the second major surface 116 of the second glass substrate 112 of the glass structure 100 (e.g., shown in FIG. 5) is omitted in the sixth laser-bonded assembly 10f. The omission of the third glass-glass laser bond 394c can reduce the process steps and time used form the sixth laser-bonded assembly 10f without foreseeable negative effect on the hermeticity of the glass structure 100.

The fixtures and processes (including laser parameters) used to form the one or more glass-glass laser bonds 394 so as to hermetically seal the glass structure 100 of the fifth laser-bonded assembly 10e and connect the glass structure 100 to the first cover glass 350 and/or the second cover glass 370 of the fifth laser-bonded assembly 10e can be used to form the one or more glass-glass laser bonds 394 so as to hermetically seal the glass structure 100 of the sixth laser-bonded assembly 10f and connect the glass structure 100 to the first cover glass 350 and/or the second cover glass 370 of the sixth laser-bonded assembly 10f.

The various embodiments of the laser-bonded assemblies 10a, 10b, 10c, 10d, 10e, 10f disclosed herein have numerous advantages over existing assemblies or devices that comprise hermetically-sealed glass structures. In particular, the inclusion of at least one cover glass (e.g., the first cover glass 300, 350) with each of the laser-bonded assemblies 10a, 10b, 10c, 10d, 10e, 10f disclosed herein along with the various configurations of the laser bonds 202, 220, 344, and/or 394 disclosed herein can address some of the existing issues related to edge strength and fixturing of the glass structures used in existing assemblies or devices. Examples of such existing issues are described hereinbelow for additional context.

To enable high volume manufacturing of glass structures, particularly those that comprise fill layer(s), the fill material can be applied to the glass at the wafer level before the wafer is singulated into the individual components/devices that form the glass structures. However, the (composite) glass structure made of glass and a fill (e.g., non-brittle, often polymer material) can be difficult to cut. This difficulty arises because brittle and ductile materials have different methods of effectively cutting, especially when cutting free-form (not straight line) shapes from the (composite) glass structures. As such, after cutting, the edge strength of the (composite) glass structure can be lower when compared to the edge strength of a glass structure made of glass only. Moreover, because the fill material can be sensitive to the environment, it may not be feasible to perform mechanical edge finishing (e.g., grind/polish) after cutting (e.g., after laser cutting).

Additionally, stress modeling suggest that when a (composite) glass structure is stressed, the two surfaces that experience the most stress are those on the interior of the part. This result can be understood in the context that the fill material is compliant, e.g., the fill material is not rigid so it can flex to some degree. The flexure as a result of this compliance can put more stress on the glass portion of the (composite) glass structure. Additionally, when a metal foil with an aperture (e.g., an aperture that exposes a central region of the glass structure) is positioned/bonded on one or both of the major surfaces of the glass structure to provide the hermetic sealing, an additional point/region of stress is formed thereon. This stress concentration is a result of the metal foil not fully covering the major surfaces of the glass structure.

These existing edge strength issues and the stress management issues can make it difficult to manufacture hermetically-sealed glass structures that comply with durability requirements and hermeticity requirements. For most consumer electronic applications, the edges must be pristine otherwise the article may not survive the impacts and stresses from normal use. In the case of a composite glass structure that comprises fill layer(s), the edge strength may be reduced after cutting, and correction of the reduced edge strength after cutting via post processing may not be possible, as noted above. Thus, the composite glass structure may not be strong enough to pass consumer tests. Additionally, while existing metal foils may adequately function as a hermetic seal, such metal foils may not be rigid enough for mounting/fixturing of the glass structure to other components of the assembly.

The laser-bonded assemblies 10a, 10b, 10c, 10d, 10c, 10f of the present disclosure address the noted existing issues and others by use of at least one cover glass (e.g., the first cover glass 300, 350) that is configured to decouple the hermeticity requirement with the handling and reliability requirements, e.g., for consumer electronic devices. In particular, the at least one cover glass can be ion exchanged (e.g., with or without edge finishing) so that it has superior edge strength and scratch resistance. In embodiments of the laser-bonded assemblies 10a, 10b, 10c that comprise a frame (e.g., formed from a metal or a similarly rigid material), the at least one cover glass can be mechanically attached to the frame so as to better handle the stresses and impacts on the glass. The edge quality of the first and second glass substrates 104, 112 of the glass structures 100 used in the laser-bonded assemblies 10a, 10b, 10c, 10d, 10c, 10f disclosed herein may be less important since the stresses on the edges of these assemblies are substantially less due to the inclusion of the at least one cover glass.

The fourth, fifth, and sixth laser-bonded assemblies 10d, 10e, 10f of the present disclosure may have additional advantages. As described hereinabove, the metal (e.g., aluminum) of the metal foil 200, 250 used in connection with the first, second, and third laser-bonded assemblies 10a, 10b, 10c is replaced with the polymer of the polymer seal 500, 550 used in connection with the fourth, fifth, and sixth laser-bonded assemblies 10d, 10c, 10f. Additionally, the metal of the frame 400, 420 used in connection with the first, second, and third laser-bonded assemblies 10a, 10b, 10c is removed and, instead, a first (three-dimensional formed) cover glass (e.g., first cover glass 350) is directly welded to a second cover glass (e.g., second cover glass 370) in the fourth, fifth, and sixth laser-bonded assemblies 10d, 10e, 10f. The hermetically-sealed glass structure 100 disclosed herein now includes laser welding as well as a polymer, which not only enhances hermiticity but also provide the following additional advantages.

The advantages associated with replacing metal (e.g., aluminum) with polymer include: problems associated with mounting/fixturing of soft aluminum can be resolved; problems associated with mismatch of mechanical, and thermal properties as well as CTE between metal (aluminum) and glass that can cause residual stresses in glass can be resolved; the process of applying and curing polymer is substantially easier, faster, and less expensive compared with laser welding; polymer can dampen the stress waves/vibrations, which can help the integrity and performance of the glass structure, specifically under dynamic loads (e.g., due to drops and falls; complexities and uncertainties in resultant composition and potential flaws (such as voids) due to mixing of two dissimilar materials (glass and aluminum) in the melting pool can be reduced by elimination of the foil; and removing the metal improves corrosion resistivity.

The advantages associated with replacing the (metal) frame with a formed cover glass include: laser welding of cover glasses is advantageous compared with its mechanical attachment to the metal frame considering hermiticity and the glass structure can be lighter.

While the disclosure has been illustrated and described in detail in the drawings and foregoing description, the same should be considered as illustrative and not restrictive in character. It is understood that only the preferred embodiments have been presented and that all changes, modifications, and further applications that come within the spirit of the disclosure are desired to be protected.

What is claimed is:

1. A laser-bonded assembly, comprising:
a glass structure that includes (i) a first glass substrate defining a first major surface, (ii) a second glass substrate disposed adjacent the first glass substrate and defining a second major surface that faces opposite the first major surface, and (iii) a peripheral edge extending between the first and second major surfaces about a periphery of the glass structure;
a metal foil encircling the peripheral edge about the periphery of the glass structure, the metal foil connected to the glass structure via one or more foil-glass laser bonds;
a first cover glass connected to one or more of the glass structure or the metal foil; and
a frame disposed adjacent the first cover glass, the glass structure and the metal foil at least partially surrounded by the frame and the first cover glass.

2. The laser-bonded assembly of claim 1, wherein the metal foil comprises a first foil portion that extends towards the glass structure and connects to the first major surface at a first contact location.

3. The laser-bonded assembly of claim 1, wherein the first foil portion comprises a first foil surface connected to the first major surface at the first contact location via a first foil-glass laser bond of the one or more foil-glass laser bonds.

4. The laser-bonded assembly of claim 1, wherein the metal foil comprises a second foil portion that extends towards the glass structure and connects to the second major surface at a second contact location.

5. The laser-bonded assembly of claim 4, wherein the second foil portion comprises a second foil surface connected to the second major surface at the second contact location via a second foil-glass laser bond of the one or more foil-glass laser bonds.

6. The laser-bonded assembly of claim 5, wherein the second foil portion connects to the first cover glass at a third contact location.

7. The laser-bonded assembly of claim 6, wherein the second foil portion comprises a third foil surface connected to the first cover glass at the third contact location via a third foil-glass laser bond of the one or more foil-glass laser bonds.

8. The laser-bonded assembly of claim 6, wherein the second foil portion comprises a third foil surface connected to the first cover glass at the third contact location via optically clear adhesive.

9. The laser-bonded assembly of claim 4, further comprising a second cover glass disposed adjacent the frame and opposite the first cover glass, the glass structure and the metal foil disposed between the first and second cover glasses.

10. The laser-bonded assembly of claim 9, wherein the first foil portion connects to the second cover glass at a fourth contact location.

11. The laser-bonded assembly of claim 10, wherein the first foil portion comprises a fourth foil surface connected to the second cover glass at the fourth contact location via a fourth foil-glass laser bond of the one or more foil-glass laser bonds.

12. The laser-bonded assembly of claim 1, wherein the metal foil comprises a second foil portion extending away from the glass structure and connecting to the first cover glass at a second contact location.

13. The laser-bonded assembly of claim 12, wherein the second foil portion comprises a second foil surface connected to the first cover glass at the second contact location via a second foil-glass laser bond of the one or more foil-glass laser bonds.

14. The laser-bonded assembly of claim 12, wherein the first cover glass is connected to the second major surface of the glass structure via a first glass-glass laser bond.

15. The laser-bonded assembly of claim 14, wherein the first glass-glass laser bond is disposed one or more of (i) laterally inwardly from the second foil-glass laser bond or (ii) substantially laterally aligned with the first foil-glass laser bond.

16. The laser-bonded assembly of claim 14, further comprising a second cover glass disposed adjacent the frame opposite the first cover glass, the glass structure and the metal foil disposed between the first and second cover glasses.

17. The laser-bonded assembly of claim 16, wherein the second cover glass is connected to the first major surface of the glass structure via a second glass-glass laser bond.

18. The laser-bonded assembly of claim 17, wherein the second glass-glass laser bond is disposed laterally inwardly from one or more of the first glass-glass laser bond, the first foil-glass laser bond, or the second foil-glass laser bond.

19. The laser-bonded assembly of claim 1, wherein each of the one or more foil-glass laser bonds extends along a respective closed contour that encircles a central region of the glass structure.

20. The laser-bonded assembly of claim 1, wherein the first cover glass is strengthened.

21. The laser-bonded assembly of claim 20, wherein the first cover glass is chemically strengthened via ion exchange.

22. A laser-bonded assembly, comprising:
a glass structure including (i) a first glass substrate defining a first major surface, (ii) a second glass substrate disposed adjacent the first glass substrate and defining a second major surface that faces opposite the first major surface, and (iii) a peripheral edge extending between the first and second major surfaces about a periphery of the glass structure;
a polymer seal encircling the peripheral edge about the periphery of the glass structure;
a first cover glass disposed adjacent the polymer seal and the glass structure; and
a second cover glass disposed adjacent the polymer seal and the glass structure and opposite the first cover glass, the glass structure and the polymer seal disposed in a cavity between the first and second cover glasses, the second cover glass connected to one or more of the glass structure or the first cover glass via one or more glass-glass laser bonds.

23. The laser-bonded assembly of claim 22, wherein the polymer seal abuts the peripheral edge of the glass structure.

24. The laser-bonded assembly of claim 22, wherein the polymer seal abuts opposed inner surfaces of the first and second cover glasses.

25. The laser-bonded assembly of claim 22, wherein at least one of the first cover glass or the second cover glass comprises a peripheral wall extending towards the other of the first cover glass or the second cover glass and at least partially defines the cavity.

26. The laser-bonded assembly of claim 25, wherein the first cover glass and the second cover glass are connected to one another at the peripheral wall via a first glass-glass laser bond of the one or more glass-glass laser bonds.

27. The laser-bonded assembly of claim 26, wherein the second cover glass is connected to the first major surface of the glass structure via a second glass-glass laser bond of the one or more glass-glass laser bonds.

28. The laser-bonded assembly of claim 27, wherein the second glass-glass laser bond is disposed laterally inwardly from the first glass-glass laser bond.

29. The laser-bonded assembly of claim 27, wherein the first cover glass is connected to the second major surface of the glass structure via a third glass-glass laser bond of the one or more glass-glass laser bonds.

30. The laser-bonded assembly of claim 22, wherein the polymer seal fills an entirety of an empty volume between the glass structure and the cavity between the first and second cover glasses.

31. The laser-bonded assembly of claim 22, wherein each of the one or more glass-glass laser bonds extends along a respective closed contour that encircles a central region of the glass structure.

32. The laser-bonded assembly of claim 22, wherein one or more of the first cover glass or the second cover glass is strengthened.

33. The laser-bonded assembly of claim 32, wherein the one or more of the first cover glass or the second cover glass is chemically strengthened via ion exchange.
